(19) United States
(12) Patent Application Publication
(10) Pub. No.: US 2026/0146371 A1
(43) Pub. Date: May 28, 2026

(54) COMPOSITE NANOWIRES AS WELL AS TRANSDUCERS AND TRANSISTORS BASED THEREON

(71) Applicant: ÉCOLE DE TECHNOLOGIE SUPÉRIEURE, Montreal (CA)

(72) Inventors: Mohamed Cherif AZZAZ, North York (CA); Nicole Raymonde DEMARQUETTE, Montreal (CA); Ricardo Johann ZEDNIK, Houston, TX (US)

(21) Appl. No.: 19/120,616

(22) PCT Filed: Oct. 13, 2023
(86) PCT No.: PCT/CA2023/051357

§ 371 Date: Apr. 11, 2025

Related U.S. Application Data
(60) Provisional application No. 63/379,305, filed on Oct. 13, 2022.

(51) Int. Cl. D01F 8/18; D01D 5/00; D01D 5/04; D01F 8/10; H10D 62/10; H10N 30/00

(52) U.S. Cl. CPC D01F 8/18; D01D 5/0038; D01D 5/04; D01F 8/10; D10B 2101/122; D10B 2321/042; D10B 2505/00; H10D 62/119; H10N 30/706

(57) ABSTRACT

Nanowire comprising an electrically conducting or semi-conducting core surrounded by an electrically insulating sheath are provided together with transducers and transistors based on these nanowires. The core of the nanowire has an average diameter of at most about 1000 nm, the nanowire has an average diameter of at most about 10 μm, and in the core, carbon nanotubes are in direct contact with each other without intervening dielectric polymer and thus form an uninterrupted conducting or semi-conducting electrical path along the length of the nanowire.

### CROSS REFERENCE TO RELATED APPLICATIONS

This application claims benefit, under 35 U.S.C. § 119(e), of U.S. provisional application Ser. No. U.S. 63/379,305, filed on Oct. 13, 2022. All documents above are incorporated herein in their entirety by reference.

### FIELD OF THE INVENTION

The present invention relates to nanowires and transistors and transducers based on these nanowires. More specifically, the present invention is concerned with composite nanowires manufactured by spinning a spinning dope.

### BACKGROUND OF THE INVENTION

### Metallic Carbon Nanotubes

Metallic carbon nanotubes are celebrated for their high electronic conductivity, including their ability to carry electric current densities that are orders of magnitude higher than copper. Indeed, carbon nanotubes do not suffer from the electromigration reliability concerns that plague copper vias and interconnects in today's Very-Large-Scale Integration (VLSI) electronic circuits. In addition, the small size and exceptional mechanical properties (high tensile strength and flexibility) of carbon nanotubes make them particularly promising candidates for the next generation of flexible electronics. Unfortunately, decades of research have been unable to provide an industrially viable pathway for assembling carbon nanotubes into the long, electrically conducting wires necessary to such applications. In addition, the deployment of carbon nanotubes is restricted by their low biocompatibility and possible toxicity.

Considerable effort has been expended to realize the exciting potential of carbon nanotubes for use in next-generation Very-Large-Scale Integration (VLSI) and novel flexible electronic devices. Single walled (SWCNT) and multiwalled (MWCNT) carbon nanotubes (CNT) exhibit great mechanical strength and flexibility in addition to interesting electrical properties driven by their unique structure and morphology^{1-1 to 1-5}.

The International Technology Roadmap for Semiconductors (ITRS) highlights the need for innovative interconnects that could support a current density of more than 10⁶ A/cm^{2 1-1 to 1-6}. MWCNTs are ballistic conductors at room temperature^{1-7 to 1-9} and can support very high current densities (of about 10⁹ A/cm²)^{1-10 to 1-12}. These exciting electrical properties have made CNTs a promising candidate for future interconnection technology, thereby replacing copper that is highly susceptible to electromigration, one of the dominant failure mechanisms in modern electronic devices¹⁻¹⁰. In addition, the superior mechanical strength and flexibility of CNTs offers the possibility of enabling a new generation of flexible electronic systems.

Unfortunately, the implementation of CNT interconnects has been hampered by significant manufacturing challenges, especially the difficulty in effectively assembling multiple CNTs into a coherent, aligned, electrically conducting wire^{1-13 to 1-15, 1-13, 1-14, 1-15}.

### Piezoelectric Devices

Piezoelectric devices are ubiquitous: they range from accelerometers in our cell-phones and automobile airbags, over fiber optic converters in undersea telecommunication cables, to ultrasound medical imaging. Countless sensors and actuators employ a piezoelectric material's ability to reversibly convert between mechanical strain and electric polarization. The vast majority of the piezoelectric materials currently in use are ceramics, including zinc oxide (ZnO), lead zirconium titanate (PZT), and barium titanate (BaTiO₃), due to their excellent piezoelectric properties [2-1 to 2-4]. Nonetheless, they all suffer from the mechanical stiffness and brittleness common to ceramics; in addition, these materials tend to be relatively difficult and expensive to manufacture, particularly in light of the continued miniaturization of everyday devices that increasingly require components on the micrometer and nanometer scale. In addition, the geometries that can be reasonably obtained using piezoelectric ceramics are largely limited to films or polyhedra.

These challenges inherent to piezoelectric ceramics have stimulated interest in exploring piezoelectric polymers, particularly polyvinylidene fluoride (PVDF) and its copolymers. Piezoelectric polymers are stretchable, flexible, chemically inert, inexpensive, and easily bulk processable into almost any desired geometry [2-5 to 2-12]. A flexible piezoelectric polymer nanofiber device would be an enabling technology with the potential to enable novel applications that are currently unthinkable with ceramics, including smart textiles that detect their own deformation, piezoelectric vascular implants, or flexible electronics devices with embedded microphones and speakers. However, piezoelectric polymers tend to suffer from significantly weaker piezoelectric coefficients than ceramics, and are challenging to integrate into micrometer and nanometer scaled devices.

Considerable effort has therefore been expended over the years to improve the piezoelectric coefficient of semi-crystalline PVDF, including by modifying the chemistry and introducing additives. One of the most promising approaches has been to manufacture PVDF nanofibers using the electrospinning process [2-13 to 2-17].

Electrospinning produces continuous nanofibers by applying an electric potential to a nozzle from which a polymer melt or solution is extruded. This electric potential acts as a driving force to stretch the polymer into a continuous fiber with a controllable diameter ˜10 μm to ˜10 nm, depending on processing parameters [2-18; 2-19]. The mechanical stretching of PVDF during the electrospinning process not only improves the polymer's crystallinity, but also increases the relative volume fraction of the piezoelectric β phase. These two structural changes combine to greatly enhance the piezoelectric behavior of this nanostructured PVDF compared to the bulk.

While this interesting manufacturing process allows for improved piezoelectric properties and a uniquely valuable form factor (long continuous nanofibers of piezoelectric material), assembling this nanostructured material into a useful piezoelectric device remains elusive. Although some authors report piezoelectric devices created by sandwiching a membrane/mat of randomly oriented electrospun fibers between two large metal electrodes [2-20 to 2-22], all such attempts have yielded unsatisfactory results: the random orientation of the fibers relative to the electrodes largely negates the material property improvement obtained by nanostructuring the PVDF. Indeed, the crystalline orientation of the β phase induced in PVDF electrospun fibers is such that the greatest piezoelectric polarization will be radially toward the center of the fiber [2-23]. This implies that any attempt at placing electrodes on either side of a fiber or collection of fibers (such as a membrane/mat) is bound to yield disappointing results, as the piezoelectric polarization vectors within the fibers will largely cancel out between the electrodes.

Therefore, a major remaining obstacle to realizing a flexible piezoelectric polymer nanofiber device is the difficulty in integrating electrodes that can harness the nanostructural advantage of these electrospun semi-crystalline nanofibers.

### SUMMARY OF THE INVENTION

In Accordance with the Present Invention, there is Provided:
1. A nanowire comprising an electrically conducting or semi-conducting core surrounded by an electrically insulating sheath,
   wherein the core comprises (preferably consists of) a plurality of carbon nanotubes and the sheath comprises (preferably consists of) a dielectric polymer,
   wherein the core has an average diameter of at most about 1000 nm and the nanowire has an average diameter of at most about 10 μm, and
   wherein, in the core, the carbon nanotubes are aligned along the longitudinal axis of the nanowire, and
   wherein, in the core, the carbon nanotubes are in direct contact with each other without intervening dielectric polymer and thus form an uninterrupted conducting or semi-conducting electrical path along the length of the nanowire.
2. The nanowires of embodiment 1, wherein the carbon nanotubes are conducting carbon nanotubes
3. The nanowires of embodiment 2, wherein the nanowires have an average core conductivity of at least about 10⁻⁵ S/cm, preferably at least about 5×10⁻⁶ S/cm, and most preferably of about 10⁻⁴ S/cm or more.
4. The nanowires of embodiment 1, wherein the carbon nanotubes are semi-conducting carbon nanotubes.
5. The nanowires of any one of embodiments 1 to 4, wherein the carbon nanotubes are single-walled carbon nanotubes or multi-walled carbon nanotubes, preferably multi-walled carbon nanotubes.
6. The nanowires of any one of embodiments 1 to 5, wherein the nanowires have an average surface conductivity of less than about 10⁻¹⁰ S/cm, preferably less than about 10⁻¹² S/cm, more preferably less than about 10⁻¹⁴ S/cm, and most preferably of about 10⁻¹⁵ S/cm or less.
7. The nanowires of any one of embodiments 1 to 6, wherein the dielectric polymer is a dielectric polymer having a surface energy substantially lower than the surface energy of the carbon nanotubes in the core.
8. The nanowires of embodiment 7, wherein the surface energy of the dielectric polymer is at least about 5 mN m⁻¹ lower than the surface energy of the carbon nanotubes, preferably at least about 7.5 mN m⁻¹ lower than the surface energy of the carbon nanotubes, more preferably at least about 10 mN m⁻¹ lower than the surface energy of the carbon nanotubes, even more preferably at least about 12.5 mN m⁻¹ lower than the surface energy of the carbon nanotubes, and most preferably at least about 15 mN m⁻¹ lower than the surface energy of the carbon nanotubes.
9. The nanowires of any one of embodiments 1 to 8, wherein the dielectric polymer is
   a fluoropolymer [such as polytetrafluoroethylene (PTFE), polyvinyl fluoride (PVF), ethylene tetrafluoroethylene (ETFE), fluorinated ethylene propylene (FEP), and polyvinylidene fluoride (PVDF)], a polyolefin [such as polyethylene, polypropylene, polybutylene], a styrenic polymer [such as polystyrene, acrylonitrile butadiene styrene, styrene butadiene styrene copolymer], a polyamide [such as polyamide-6,6, polyamide-6-10, polyamide-11], or a polyester [such as polyethylene terephthalate, polypropylene terephthalate, polybutylene terephthalate, poly(I-lactic acid)],
   preferably a fluoropolymer, and
   most preferably PVDF.
10. The nanowires of any one of embodiments 1 to 9, wherein the dielectric polymer is chemically inert and/or biocompatible, preferably both.
11. The nanowires of any one of embodiments 1 to 10, wherein the carbon nanotubes have an average diameter of at least about 0.4 nm, preferably at least about 1 nm, more preferably at least about 2.5 nm, yet more preferably at least about 5 nm, even more preferably at least about 7.5 nm, and most preferably at least about 10 nm.
12. The nanowires of any one of embodiments 1 to 11, wherein the carbon nanotubes have an average diameter of at most about 100 nm, preferably at most about 75 nm, more preferably at most about 50 nm, yet more preferably at most about 25 nm, even more preferably at most about 15 nm, and most preferably at most about 10 nm.
13. The nanowires of any one of embodiments 1 to 12, wherein the carbon nanotubes have an average diameter of about 10 nm.
14. The nanowires of any one of embodiments 1 to 13, wherein the core is made of single carbon nanotubes arranged end-to-end and not substantially overlapping each other.
15. The nanowires of any one of embodiments 1 to 13, wherein the core is made of bundles of carbon nanotubes, with the nanotubes are arranged end-to-end as well as side-by-side.
16. The nanowires of any one of embodiments 1 to 15, wherein the core has an average diameter of at least about 0.4 nm, preferably at least about 1 nm, more preferably at least about 2.5 nm, yet more preferably at least about 5 nm, even more preferably at least about 7.5 nm, and most preferably at least about 10 nm.
17. The nanowires of any one of embodiments 1 to 16, wherein the core has an average diameter of at most about 750 nm, preferably at most about 500 nm, more preferably at most about 250 nm, even more preferably at most about 100 nm, yet more preferably at most about 75 nm, more preferably at most about 50 nm, even more preferably at most about 25 nm, and most preferably at most about 10 nm.
18. The nanowires of any one of embodiments 1 to 17, wherein the core has an average diameter of about 10 nm.
19. The nanowires of any one of embodiments 1 to 18, wherein the insulating sheath is at least about 5 nm thick, preferably at least about 10 nm thick, more preferably at least about 15 nm thick, yet more preferably at least about 20 nm thick, even more preferably at least about 25 nm thick, more preferably at least about 30 nm thick, and most preferably at least about 35 nm thick.
20. The nanowires of any one of embodiments 1 to 19, wherein the insulating sheath is at most about 5 μm thick, preferably at most about 2.5 μm thick, more preferably at most about 1 μm thick, even more preferably at most about 500 nm thick, yet more preferably at most about 250 nm thick, even more preferably at most about 100 nm thick, and most preferably at most about 50 nm think.
21. The nanowires of any one of embodiments 1 to 20, wherein the insulating sheath is about 35 nm or about 45 nm thick.
22. The nanowires of any one of embodiments 1 to 21, having an average diameter of at least about 10.4 nm, preferably at least about 15 nm, preferably at least about 25 nm, preferably at least about 50 nm, preferably at least about 60 nm, preferably at least about 70 nm, and most preferably at least about 80 nm.
23. The nanowires of any one of embodiments 1 to 22, having an average diameter of at most about 5 μm, preferably at most about 1000 nm, more preferably at most about 500 nm, yet more preferably at most about 200 nm, even more preferably at most about 150 nm, and most preferably at most about 100 nm.
24. The nanowires of any one of embodiments 1 to 23, having an average diameter of about 80 nm or about 100 nm.
25. A method for manufacturing the nanowires of any one of embodiments 1 to 24, the method comprising:
   A) providing a spinning dope comprising the dielectric polymer, the carbon nanotubes, and a solvent or a mixture thereof, and
   B) spinning the spinning dope.
26. The method of embodiment 25, wherein the spinning dope comprises a mixture of solvents, preferably a mixture of n,n-dimethylformamide (DMF) and acetone, and most preferably a 7:3 mixture (by weight) of DMF and acetone.
27. The method of embodiment 25 or 26, wherein the concentration of the polymer in the spinning dope is from about 10 to about 30 w/w % and is preferably about 15 w/w %, all percentages being based on the total weight of the polymer and the solvent mixture.
28. The method of any one of embodiments 25 to 26, wherein the concentration of the carbon nanotubes in the spinning dope is at least about 0.5 w/w %.
29. The method of any one of embodiments 25 to 28, comprising:
   A)_providing a spinning dope comprising the dielectric polymer, the carbon nanotubes, and a solvent or a mixture thereof, and
   B′) electrospinning the spinning dope.
30. The method of embodiment 29, comprising at step B′), feeding the spinning dope to a spinneret while applying an electrical potential to the spinneret relative to a collector such that a jet of spinning dope forms and is collected as a nanowire on the collector.
31. The method of embodiment 29 or 30, wherein, at step B′), the electrospinning is carried out under one or more (preferably all) of the following conditions:
spinneret: hollow stainless steel needle with diameter 0.361 mm (27 g)
flow rate of 1 mL/h,
electrically grounded rotating cylindrical collector (diameter of 7.5 cm) with a rotation speed of 400 rpm,
working distance: 20 cm, and/or
electric field of 1.25×10⁵ V/m applied between the needle and the collector using a high voltage power supply.
32. The method of any one of embodiments 25 to 28, comprising:
   A) providing a spinning dope comprising the dielectric polymer, the carbon nanotubes, and a solvent or a mixture thereof, and
   B″) blowspinning the spinning dope.
33. The method of embodiment 32, comprising at step B′), feeding the spinning dope to an inner nozzle of a spinneret while feeding pressurized gas to an outer nozzle of said spinneret such that a jet of spinning dope forms and is collected as a nanowire on a collector, wherein the inner nozzle and the outer nozzle are coaxial.
34. The method of any one of embodiments 25 to 31, wherein, at step B), the electrospinning is carried out under one or more (preferably all) of the following conditions:
   spinneret: hollow needle with diameter 0.361 mm (27 g)
   spinning dope flow rate of 33 L/min,
   compressed air was delivered at a constant pressure of 140 kPa, and
   working distance: 20 cm.
35. The method of embodiment 30 or 33, wherein the collector is planar, a rotating drum, a treadmill, a ring, or of another shape.
36. The method of embodiment 35, wherein the collector is static or dynamic.
37. A piezoelectric transducer comprising the nanowire of any one of embodiments 1 to 3 and 5 to 24 and an electrically conductive sheath surrounding the nanowire, wherein the dielectric polymer in the electrically insulating sheath is a piezoelectric polymer and the carbon nanotube is a metallic carbon nanotube.
38. The transducer of embodiment 37, wherein the piezoelectric polymer is polyvinylidene fluoride (PVDF), poly(I-lactic acid) (PLA) or their copolymers,
39. The transducer of embodiment 37 or 38, wherein the piezoelectric polymer is PVDF.
40. The transducer of embodiment 39, wherein the PVDF is at least about 10% crystalline, preferably at least about 20% crystalline, more preferably at least about 33% crystalline, yet more preferably at least about 40% crystalline, and most preferably at least about 50% crystalline.
41. The transducer of 40, wherein the PVDF is about 50% crystalline.
42. The transducer of any one of embodiments 34 to 41, wherein the PVDF has a crystalline volume fraction of crystalline β phase of at least about 10%, preferably at least about 20%, more preferably at least about 33%, yet more preferably at least about 40%, and most preferably of at least about 50% crystalline.
43. The transducer of embodiment 42, wherein the PVDF has a crystalline volume fraction of crystalline β phase of about 53%
44. The transducer of embodiment 42 or 43, wherein the crystalline β phase of the PVDF is oriented with a [001] direction along the longitudinal axis of the transducer and with the [100] direction perpendicular to the longitudinal axis of the transducer.
45. The transducer of any one of embodiments 37 to 44, wherein the electrically insulating sheath further comprises a piezoelectric ceramic, preferably as nanoparticles, dispersed in a matrix of the piezoelectric polymer.
46. The transducer of embodiment 45, wherein the piezoelectric ceramic is barium titanate, lead zirconium titanate, barium strontium titanate, lithium niobate, or aluminum nitride.
47. The transducer of any one of embodiments 37 to 76, wherein the transducer has an average diameter between about 29 nm and about 450 nm and most preferably of about 80 nm.
48. The transducer of any one of embodiments 38 to 47, wherein the core has an average diameter between about 5 nm and about 50 nm and most preferably of about 10 nm.
49. The transducer of any one of embodiments 38 to 48, wherein the electrically insulating sheath has a thickness between about 10 nm and 100 nm and most preferably of about 33 nm.
50. The transducer of any one of embodiments 38 to 49, wherein the electrically conducting sheath has a thickness between about 2 nm and about 100 nm, and most preferably of about 5 nm.
51. The transducer of any one of embodiments 38 to 50, wherein the electrically conducting sheath is made of a conducting metal,
   preferably copper, silver, palladium, platinum, iridium, graphite, graphene, aluminum, titanium, or gold, or an alloy or composite thereof,
   more preferably gold or an alloy or composite thereof,
   most preferably gold.
52. A transistor comprising the nanowire of any one of embodiments 1 and 4 to 24, wherein the carbon nanotube is a semi-conducting carbon nanotube, and wherein the nanowire is surrounded by a conductive sheath.
53. The transistor of embodiment 52, having an average diameter between about 29 nm and about 450 nm, most preferably of about 80 nm.
54. The transistor of embodiment 52 or 53, wherein the core has an average diameter between about 5 nm and about 50 nm, and most preferably of about 10 nm.
55. The transistor of any one of embodiments 52 to 54, wherein the electrically insulating sheath has a thickness between about 10 nm and about 100 nm, and most preferably of about 30 nm.
56. The transistor of any one of embodiments 52 to 55, wherein the electrically conducting sheath has a thickness between about 2 nm and about 100 nm, and most preferably of about 5 nm.
57. The transistor of any one of embodiments 52 to 56, wherein the electrically conducting sheath is made of a conducting metal,
   preferably copper, silver, palladium, platinum, iridium, graphite, graphene, aluminum, titanium, or gold, or
   an alloy or composite thereof,
   more preferably gold or an alloy or composite thereof,
   most preferably gold.
58. A method for manufacturing the piezoelectric transducer of any one of embodiments 37 to 51 or the transistor of any one of embodiments 52 to 57, the method comprising:
   i. providing a nanowire using the method of any one of embodiments 25 to 36, and
   ii. covering the nanowire with the conductive sheath.
59. The method of embodiment 58, wherein step ii is carried out by physical vapor deposition, sputtering, dip coating, powder coating, electrochemical deposition, painting, plasma vapor deposition, chemical bath deposition, spray painting, screen printing, or electron beam deposition, preferably by physical vapor deposition.
60. The method of embodiment 58 or 59 further comprising assembling a plurality of transducers or a plurality of transistors in a bundle with their exposed ends joined with a conducting material and their conducting sheaths making electrical contact with each other.

### BRIEF DESCRIPTION OF THE DRAWINGS

### In the Appended Drawings:

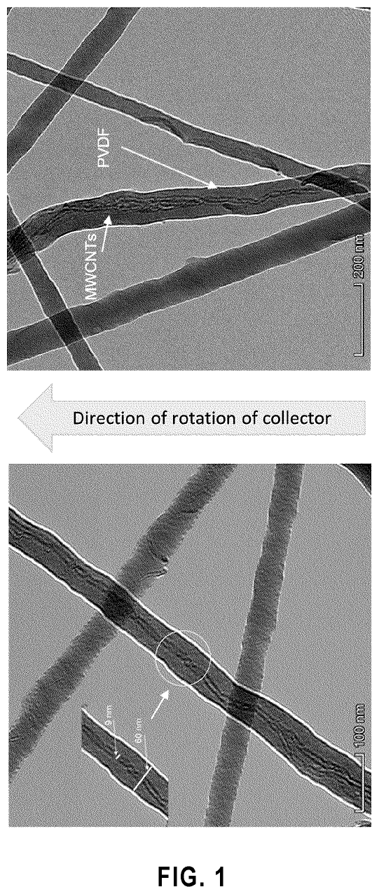

FIG. 1 shows representative TEM images (0.6% wt. MWCNT concentration) confirming the alignment of MWCNTs to form a continuous electrically conductive core coaxially enveloped by an insulating fluoropolymer sheath.

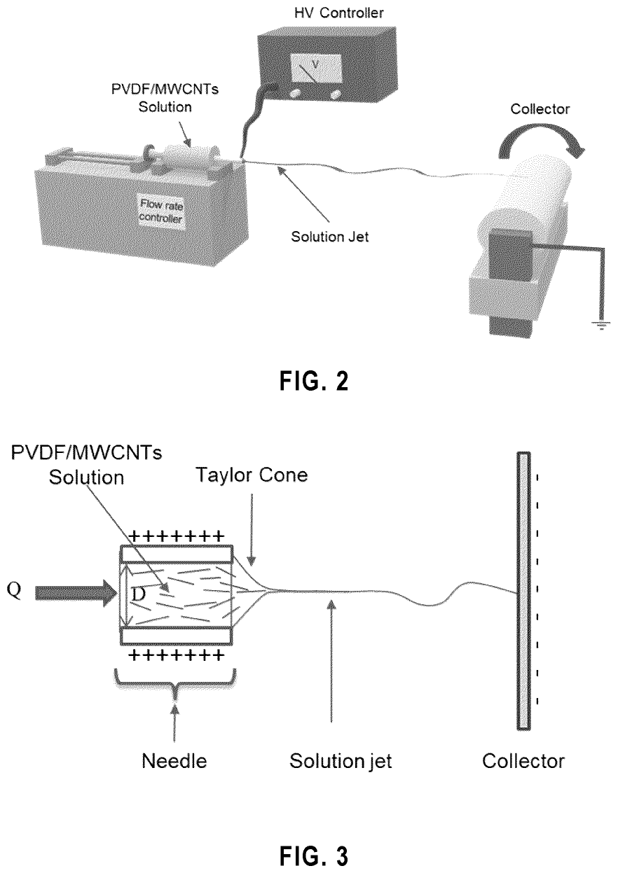

FIG. 2 is a schematic showing an electrospinning setup.

FIG. 3 is a closeup view of the electrospinning setup.

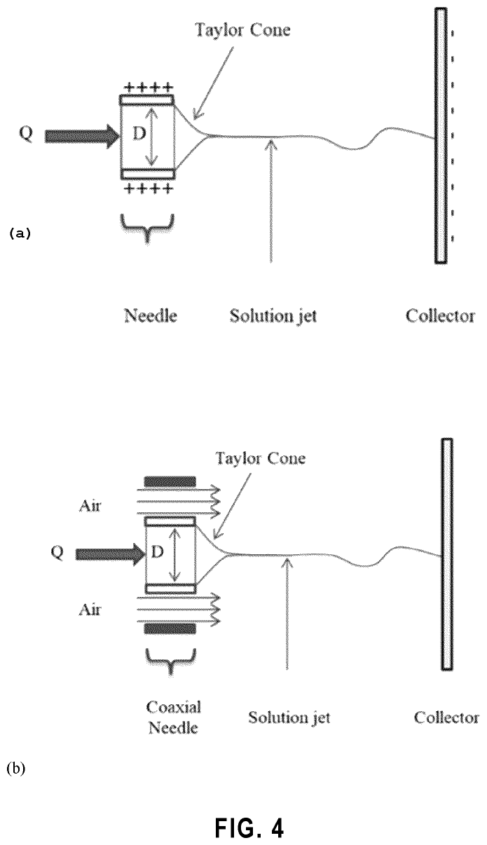

FIGS. 4(a) and (b) are schematics showing a polymer solution being extruded with a flow rate Q through a nozzle of inner diameter D using either (a) Solution electrospinning (SES) process, or (b) Solution blowspinning (SBS) process.

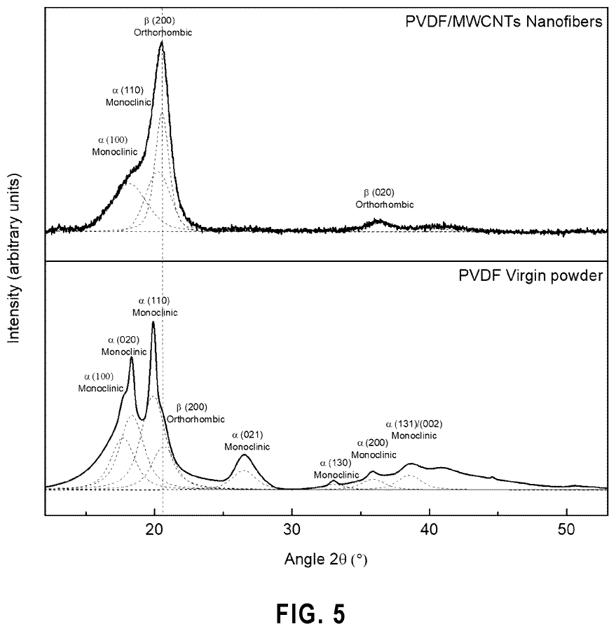

FIG. 5 is a representative X-ray diffractogram of electrospun PVDF/MWCNTs nanofibers compared to PVDF virgin powder.

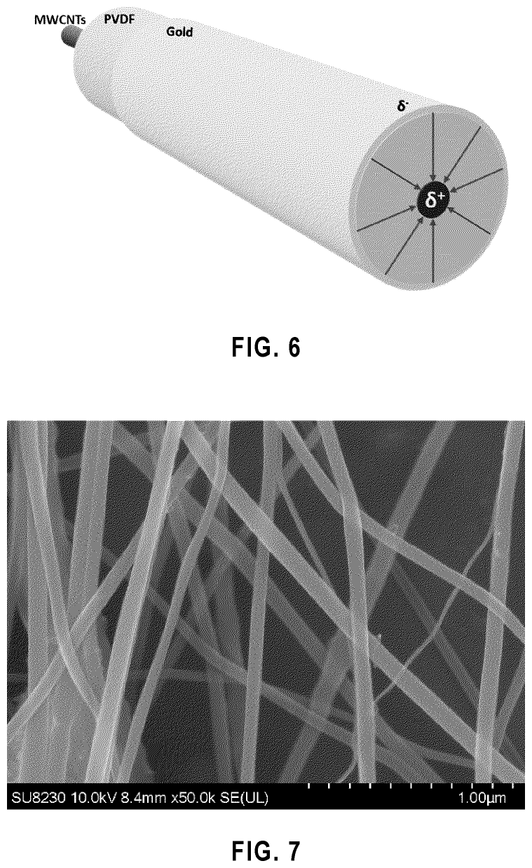

FIG. 6 is a schematic representation of a PVDF nanofiber device, showing direction of piezoelectric polarization. The inner electrode consists of a MWCNT core and the outer electrode consists of a PVD gold thin-film.

FIG. 7. is a representative SEM image of composite nanofibers of fluoropolymer and 0.6% wt. MWCNTs obtained by electrospinning process.

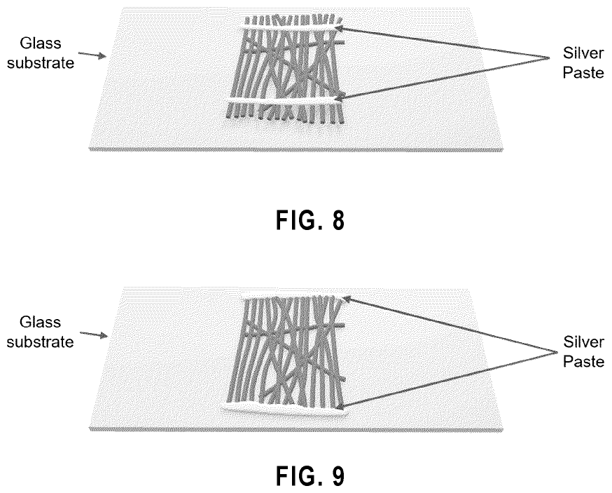

FIG. 8 is an illustration showing the contact between electrodes and nanofibers using silver paste and measurement method of average surface conductivity.

FIG. 9 is an illustration showing the contact between electrodes and nanofibers using silver paste and measurement method of average core conductivity.

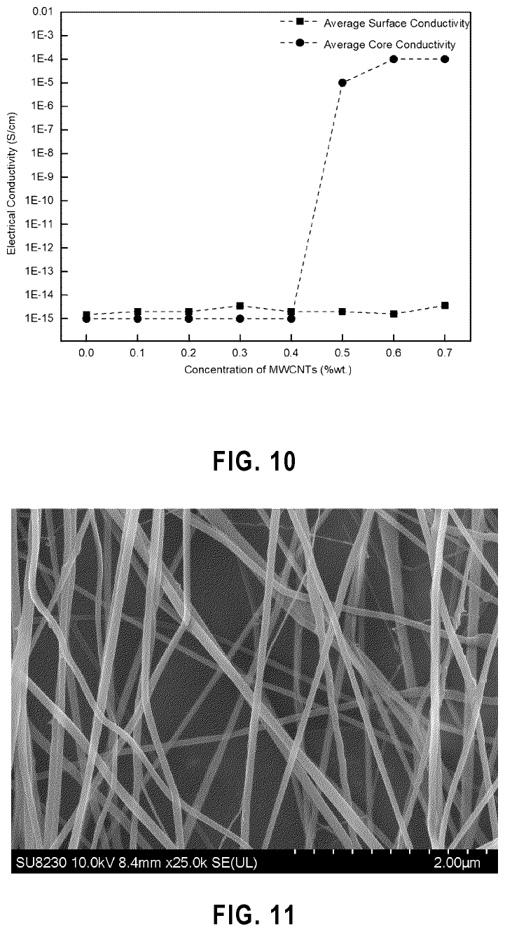

FIG. 10 shows the average electrical conductivity of nanofibers as a function of MWCNT concentration.

FIG. 11 is a representative SEM image of PVDF/MWCNTs nanofibers produced by electrospinning process.

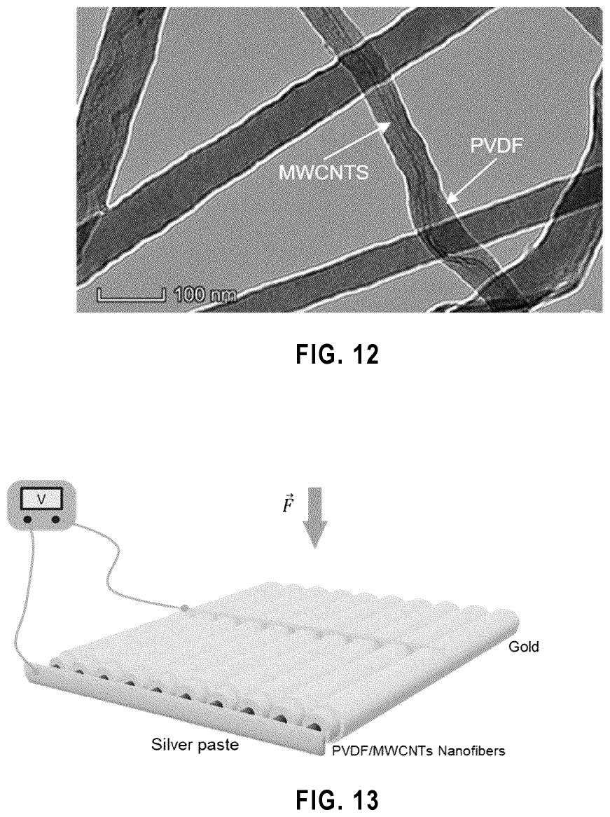

FIG. 12 is a representative TEM image of nanofibers obtained by electrospinning technique showing a core of MWCNT (identified with arrows) enrobed by PVDF.

FIG. 13 is a schematic showing how the direct piezoelectric effect was measured by applying a mechanical load on the piezoelectric nanofibers.

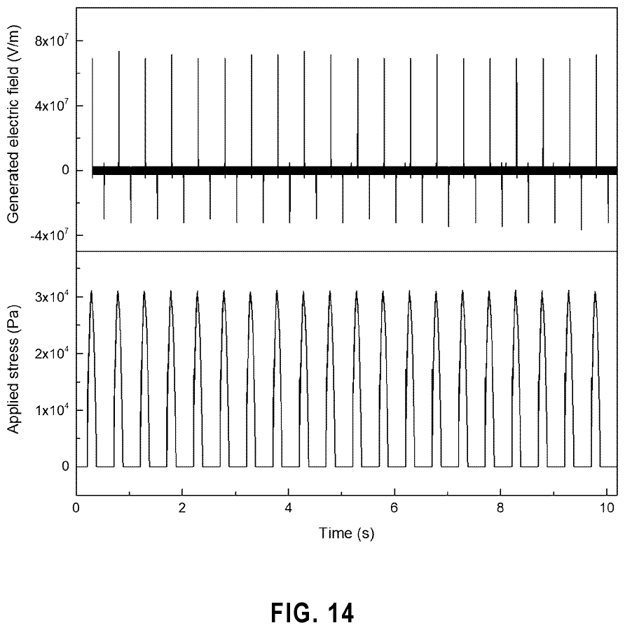

FIG. 14 shows the applied mechanical stress on the nanofiber assembly and the generated electric field within the nanofibers.

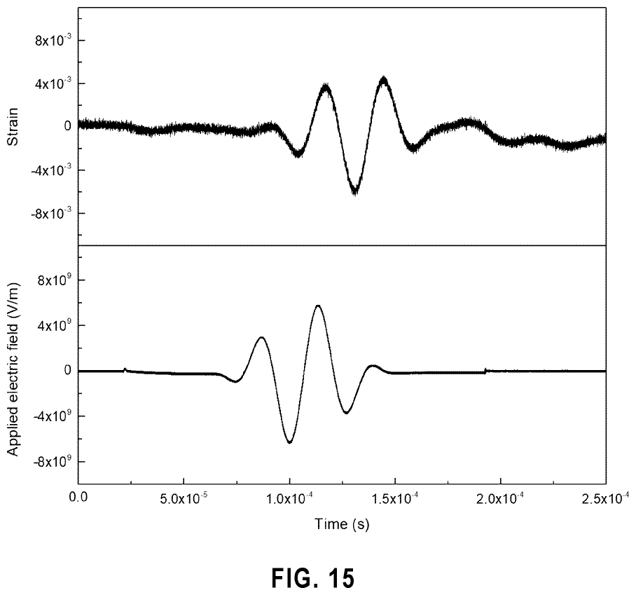

FIG. 15 shows the electric field applied across PVDF nanofibers and the resulting mechanical strain.

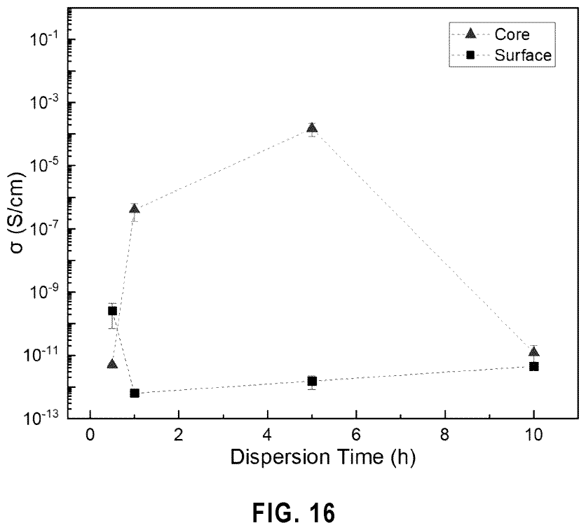

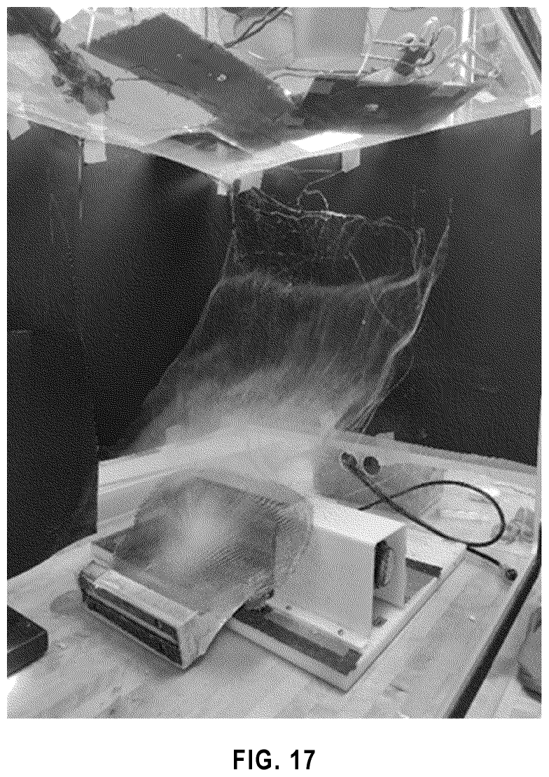

FIG. 16 shows the core and surface conductivity of fibers as a function of the dispersion time used to prepare the spinning dope.

FIG. 17 is a picture of fiber form by blowspinning.

### DETAILED DESCRIPTION OF THE INVENTION

### Nanowire

Turning now to the invention in more details, in a first aspect of the invention, there are provided a nanowire comprising an electrically conducting or semi-conducting core surrounded by an electrically insulating sheath,
wherein the core comprises (preferably consists of) a plurality of carbon nanotubes and the sheath comprises (preferably consists of) a dielectric polymer,
wherein the core has an average diameter of at most about 1000 nm and the nanowire has an average diameter of at most about 10 μm, and
wherein, in the core, the carbon nanotubes are aligned along the longitudinal axis of the nanowire, and
wherein, in the core, the carbon nanotubes are in direct contact with each other without intervening dielectric polymer and thus form an uninterrupted conducting or semi-conducting electrical path along the length of the nanowire.

In other words, the nanowire of the invention is an electrically conducting (or semi-conducting) coaxial nanowire comprising an electrically insulating sheath. These nanowires typically have a smooth surface. Their length is not particularly limited. This electrically conducting coaxially-insulated nanowire is a particularly promising solution for replacing copper vias and interconnects in today's Very-Large-Scale Integration (VLSI) electronic circuits, as well as use in flexible electronics, including those of biomedical applications. In the case of semi-conducting coaxial nanowires, this is a particularly promising solution for flexible transistors based on semi-conducting SWCNTs. The nanowire of the invention offers the elusive promise of finally employing the exciting properties of individual SWCNTs and MWCNTs at the industrial scale while mitigating the known biotoxicity of CNTs.

The above arrangement of the carbon nanotubes in the nanowire of the invention has significant advantages.

In particular, since the carbon nanotubes are in direct contact with each other without intervening dielectric polymer, it is less likely that the core electrical conductivity (or semi-conductivity) be substantially compromised. As a result and as noted above, the carbon nanotubes form an uninterrupted conducting or semi-conducting electrical path along the length of the nanowire.

For example, in example 1 below, a bundle of comparative nanowires containing so little CNTs that they could not form an uninterrupted conducting electrical paths along the length of the nanowires had equally low average electrical conductivities for BOTH the surface of the nanowires and their cores, at around 10⁻¹⁵ S/cm. In contrast, a similarly bundle of nanowires of the invention, containing enough CNTs, had an average core conductivity of about 104 S/cm, an increase by over 10 orders of magnitude that confirmed that an uninterrupted electrical pathway along the nanofiber cores had formed. At the same time, the average surface conductivity remained unchanged showing the electrically conductive cores are enrobed by an insulating sheath. This insulating sheath, of course, prevents short-circuits. Also, in combination with the conductive core, it produced a true insulated electrically conducting nanowire.

It will be understood by the skilled person that, due to the self-assembly involved in the manufacturing of the nanowire of the invention (see next section for more details), some nanowires in a bundle of nanowires of the invention may not comprise carbon nanotubes forming an uninterrupted conducting or semi-conducting electrical path along the length of the nanowire. In other words, the electrical path may be interrupted in some nanowires. Therefore, when average conductivities are discussed herein, they represent an average over multiple nanowires, some of which may have an interrupted electrical path (while the remaining nanowires have uninterrupted electrical path). It should be noted that the number of nanowires having an interrupted electrical path may be reduced by a tight control of the manufacturing conditions.

The carbon nanotubes in the nanowire of the invention can be any electrically conducting or semi-conducting carbon nanotubes. In embodiments, conducting carbon nanotubes (also called “metallic carbon nanotubes”) are used and the core of the nanowire is conducting. Such metallic carbon nanotubes have a high electrical conductivity due to ballistic electron transport. In embodiments, semi-conducting carbon nanotubes are used and the core of the nanowire is semi-conducting. The carbon nanotubes (CNTs) can be single-walled carbon nanotubes (SWCNTs) or multi-walled carbon nanotubes (MWCNTs). In preferred embodiments, the carbon nanotubes are multi-walled carbon nanotubes.

In embodiments using metallic carbon nanotubes, the nanowires have an average core conductivity of at least about 10⁻⁵ S/cm, preferably at least about 5×10⁻⁵ S/cm, and most preferably of about 10⁻⁴ S/cm or more. In preferred embodiments, the nanowires have an average surface conductivity of less than about 10⁻¹⁰ S/cm, preferably less than about 10⁻¹² S/cm, more preferably less than about 10⁻¹⁴ S/cm, and most preferably of about 10⁻¹⁵ S/cm or less.

The core conductivity and average surface conductivity can be measured using the ASTM-D4496 method.

In embodiments, the dielectric polymer is a dielectric polymer having a surface energy substantially lower than the surface energy of the carbon nanotubes in the core. Such surface energies can be found in the literature as well as calculated or measured using e.g., the methods provided in Wendt, D. K. O. R. C. Estimation of the surface free energy of polymers. Journal of Applied Polymer Science 13, 1741-1747 (1969); Wu, S. Calculation of interfacial tension in polymer systems. Journal of Polymer Science Part C 34, 19-30 (1971); Nuriel, S., Liu, L., Barber, A. H. & Wagner, H. D. Direct measurement of multiwall nanotube surface tension. Chemical Physics Letters 404, 263-266, doi:10.1016/j.cplett.2005.01.072 (2005); Shimizu, R. N., Demarquette N. R. Evaluation of Sourface Energy of Solid Polymers Using Different Models. Journal of Applied Polymer Science 76, 1831-1845 (2000); and Wu, S. Polymer Interface and Adhesion; Marcel Dekker: New York (1982), all incorporated herein by reference.

In preferred embodiments, the surface energy of the dielectric polymer is at least about 5 mN m⁻¹, preferably at least about 7.5 mN m⁻¹, more preferably at least about 10 mN m⁻¹, even more preferably at least about 12.5 mN m⁻¹, and most preferably at least about 15 mN m⁻¹ lower than the surface energy of the carbon nanotubes. Note that in general, carbon nanotubes have a surface energy between about 28 and 46 mN m⁻¹, preferably of about 45 mN m⁻¹.

In embodiments, the dielectric polymer is a fluoropolymer [such as polytetrafluoroethylene (PTFE), polyvinyl fluoride (PVF), ethylene tetrafluoroethylene (ETFE), fluorinated ethylene propylene (FEP), and polyvinylidene fluoride (PVDF)], a polyolefin [such as polyethylene, polypropylene, polybutylene], a styrenic polymer [such as polystyrene, acrylonitrile butadiene styrene, styrene butadiene styrene copolymer], a polyamide [such as polyamide-6,6, polyamide-6-10, polyamide-11], or a polyester [such as polyethylene terephthalate, polypropylene terephthalate, polybutylene terephthalate, poly(I-lactic acid)]. In preferred embodiments, the dielectric polymer is a fluoropolymer, preferably PVDF.

In preferred embodiments, the dielectric polymer is chemically inert and/or biocompatible, preferably both.

Carbon nanotubes are generally defined as having an average diameter of 100 nm or less. The smallest reported nanotubes are about 0.4 nm in average diameter. In embodiments, the carbon nanotubes in the nanowire of the invention have an average diameter of at least about 0.4 nm, preferably at least about 1 nm, more preferably at least about 2.5 nm, yet more preferably at least about 5 nm, even more preferably at least about 7.5 nm, and most preferably at least about 10 nm. In embodiments, the carbon nanotubes in the nanowire of the invention have an average diameter of at most about 100 nm, preferably at most about 75 nm, more preferably at most about 50 nm, yet more preferably at most about 25 nm, even more preferably at most about 15 nm, and most preferably at most about 10 nm. In most preferred embodiments, the carbon nanotubes in the nanowire of the invention have an average diameter of about 10 nm.

As noted above, the core of the nanowires of the invention comprises a plurality of carbon nanotubes, aligned longitudinally, and forming an uninterrupted conducting or semi-conducting electrical path along the length of the nanowire.

Any point along the length of the nanowire, a cross-section of the core comprises a cross-section of at least one carbon nanotube.

When the cross-section of the core comprises a cross-section of a single carbon nanotube, the diameter of the core is the diameter of said single nanotube. This means that the core is made of single carbon nanotubes arranged end-to-end and that do not substantially overlap. In such embodiments, the nanotubes may for example only overlap at their ends. In other words, all cross-sections of the core along the length of the nanowire would contain a cross-section of a single carbon nanotube except for cross-sections that contain cross-section for two overlapping nanotube ends. This is shown in FIG. 1 (left).

When the cross-section of the core comprises a cross-section of a bundle of carbon nanotubes (i.e., of two or more nanotubes), the diameter of the core is the diameter of said bundle. This means that the core is made of bundles of carbon nanotubes, with the nanotubes are arranged end-to-end as well as side-by-side. This is shown in FIG. 1 (right).

As noted above, the core has an average diameter of at most about 1000 nm, preferably at most about 750 nm, more preferably at most about 500 nm, at most about 250 nm, at most about 100 nm, at most about 75 nm, at most about 50 nm, at most about 25 nm, at most about 10 nm, and at most about 5 nm. Of course, the minimum diameter of the core is the diameter of a single carbon nanotube. In preferred embodiments, the core has an average diameter of at least about 0.4 nm, preferably at least about 1 nm, more preferably at least about 2.5 nm, yet more preferably at least about 5 nm, even more preferably at least about 7.5 nm, and most preferably at least about 10 nm. In more preferred embodiments, the core has an average diameter of at most about 10 nm.

The electrically insulating sheath is of a sufficient thickness to fulfill its purpose. In embodiments, the insulating sheath is at least about 5 nm thick, preferably at least about 10 nm thick, more preferably at least about 15 nm thick, yet more preferably at least about 20 nm thick, even more preferably at least about 25 nm thick, more preferably at least about 30 nm thick, and most preferably at least about 35 nm thick. In embodiments, the insulating sheath is at most about 5 μm thick, preferably at most about 2.5 μm thick, more preferably at most about 1 μm thick, even more preferably at most about 500 nm thick, yet more preferably at most about 250 nm thick, even more preferably at most about 100 nm thick, and most preferably at most about 50 nm think. In embodiments, the insulating sheath is about 35 nm or about 45 nm thick.

In embodiments, the nanowire has an average diameter of at least about 10.4 nm, preferably at least about 15 nm, preferably at least about 25 nm, preferably at least about 50 nm, preferably at least about 60 nm, preferably at least about 70 nm, and most preferably at least about 80 nm.

As noted above, the nanowire has an average diameter of at most about 10.75 μm, preferably at most about 5 μm, more preferably at most about 1000 nm, even more preferably at most about 500 nm, yet more preferably at most about 200 nm, even more preferably at most about 150 nm, and most preferably at most about 100 nm.

In embodiments, the nanowire has an average diameter of about 80 nm or about 100 nm.

The length of the nanowire is not particularly limited.

### Method of Making the Nanowire

In a related aspect of the invention, there is provided a method for manufacturing the above nanowire. This method capitalizes on the self-assembly of carbon nanotubes and a dielectric polymer into a carbon nanotube core covered by an insulating sheath of the polymer when a spinning dope containing the polymer and the carbon nanotubes is spun. This self-assembly of carbon nanotubes by spinning a spinning dope (e.g., blowspinning and electrospinning) is very surprising.

This self-assembly is achieved by manipulating the thermodynamic driving forces during formation of the wet fiber while ensuring adequate reaction kinetics are maintained during solidification. This requires appropriately selecting the nanowire components (polymer and nanotubes) such that their relative surface energies are balanced with the mechanical extension force imposed by the air flow in the outer nozzle (blowspinning) or the electrostatic attraction between the spinneret and the collector (electrospinning). This is achieved by using a dielectric polymer having a surface energy substantially lower than the surface energy of the carbon nanotubes in the core as noted in the preceding section.

The process described provides for sufficient time for the components to segregate into the desired coaxial structure during flight of the wet fiber, including alignment and percolation of MWCNTs, while allowing for adequate molecular mobility so that the nucleation and growth of the fluoropolymer insulating sheath can occur and solidify prior to arriving at the collector.

The higher total surface energy of the carbon nanotubes means that there is a strong thermodynamic driving force preventing the carbon nanotubes from migrating to the surface of the nanowires. In addition, the relatively high surface energy of the carbon nanotubes encourages percolation and therefore allows for the formation of a conductive core. This suggests that a wide range of fluoropolymers or other low-surface energy dielectric polymers can also be used as an insulating sheath to produce nanowires of the invention by spinning a spinning dope. The carbon nanotubes can vary as long as their total surface energy remains sufficiently above that of the low-surface energy of the selected dielectric polymer.

This is a fully scalable, single-step self-assembly manufacturing approach, which enables the mass-production of the above nanowire.

### In Embodiments, the Method of the Invention Comprises the Following Steps:

A) providing a spinning dope comprising the dielectric polymer, the carbon nanotubes, and a solvent or a mixture thereof, and
B) spinning the spinning dope.

In embodiments, the spinning is electrospinning or blowspinning.

### In Embodiments, the Method of the Invention Comprises:

A)_providing a spinning dope comprising the dielectric polymer, the carbon nanotubes, and a solvent or a mixture thereof, and
B′) electrospinning the spinning dope.

As noted above, electrospinning employs electrostatic attraction to extrude nanofibers and, as such only dielectric materials can be electrospun. Carbon nanotubes are typically considered not electrospinnable, as their high electrical conductivity (or semi-conductivity) would create an electrical short circuit and cause the electrospinning process to collapse. We resolved this conundrum by encapsulating a continuous self-assembled core of carbon nanotubes with a dielectric polymer. Indeed, the use of a polymer with a low surface energy compared to the CNTs e.g., a fluoropolymer such as PVDF, helps enrobe the CNTs in an insulating sheath, thereby resolving the problem of electrospinnability of CNTs.

### In Embodiments, the Method of the Invention Comprises:

A) providing a spinning dope comprising the dielectric polymer, the carbon nanotubes, and a solvent or a mixture thereof, and
B″) blowspinning the spinning dope.

### Step A)—Spinning Dope Preparation

In the spinning dope, the polymer is dissolved in the solvent (or mixture thereof), while the carbon nanotubes are suspended in it.

The solvent or mixture thereof can comprise any solvent that can dissolve the polymer and forms a spinning dope that can be spun. In particular, it means that the solvent must evaporate in a time frame compatible with spinning. In embodiments, the spinning dope comprises a mixture of solvents, preferably a mixture of N,N-dimethylformamide (DMF) and acetone, and most preferably a 7:3 mixture (by weight) of DMF and acetone.

To prepare the spinning dope, the carbon nanotubes are dispersed within the solvent (or the mixture thereof). The PVDF is preferably added after the carbon nanotubes have been dispersed. Such dispersion can be achieved by mixing the carbon nanotubes/solvent(s) mixture. An appropriate mixing technique to achieve dispersion is ultrasonication. The dispersion time should be long enough to yield a spinning dope that is uniform or “homogeneous” as reported in Examples 1 and 2. Care should be taken to not overmix as this can lead to undesirable breakage of carbon nanotube aggregates. In the conditions reported in Examples 1 to 3, a dispersion time of between about 1 h and about 8 h can be used, with a dispersion time of about 4 h to about 6 h being preferred, and a dispersion time of about 5 h being most preferred.

The concentration of the polymer in the spinning dope is adjusted so the spinning dope has a viscosity allowing spinning. Within that range, the viscosity of the spinning dope can be adjusted to achieve various nanowire diameters. A more viscous spinning dope will yield thicker nanowires while a more fluid spinning dope will yield thinner wires. Note that the molecular weight of the polymer will also affect the viscosity of the spinning dope with heavier polymers yielding more viscous spinning dope. For example, in the conditions noted in Example 1, the concentration could be from about 10 to about 30 w/w % and a preferred concentration was about 15 w/w %, all percentages being based on the total weight of the polymer and the solvent mixture.

The concentration of the carbon nanotubes in the spinning dope can also vary. However, it must be sufficient for the carbon nanotubes to form an uninterrupted conducting or semi-conducting electrical path along the length of the nanowire. As is well known to the skilled person, the concentration must be high enough to allow for percolation, but low enough to ensure that the viscosity of the spinning dope does not impede spinnability. The exact concentration rage will depend on several factors such as for example the characteristics (Mw, length, and such) of polymer and CNTs, the exact solvent(s) used, and the spinning conditions and setup. For example, in the conditions noted in Example 1, the minimum concentration was about 0.5 w/w % (0.4 w/w % did not work).

### Step B)—Spinning

In the method of the invention, a spinning dope comprising both the polymer and CNTs is used and the nanowire is formed by segregation of the CNT from the polymer and self-assembly of the CNT to form the core of the nanowire during the spinning process.

Notably, step B) does not involve coaxial spinning of two different dopes (as in coaxial electrospinning for example). Coaxial spinning is a method in which a first spinning dope is fed to an inner spinneret and a second spinning dope (different from the first spinning dope) is fed an outer spinneret, the outer and inner spinneret being coaxial; with the inner spinneret being nested inside the outer spinneret. Such coaxial spinning of two different dopes cannot yield a core with a diameter that is that as small as that observed herein, let along that of a single nanotube. It is rather limited to produce larger cores.

Of note, the rate of solvent evaporation (determined by relative humidity, temperature, and solvent composition) and suspension viscosity (determined by component concentration and solvent composition) during wet fiber flight must be controlled such that the solidification into a dry nanofiber can occur prior to arriving at the collector. Such adjustments are well withing the purview of the skilled person.

The type of collector used for collecting the nanowire is not particularly limited. It can be planar, a rotating drum, a treadmill, a ring, or of another shape. The collector can be either be static (immovable) or dynamic (movable).

### Step B′)—Electrospinning

FIG. 2 shows a typical electrospinning setup in which a high electrical potential is applied between a spinneret and a collector. In this preferred embodiment, the spinneret is a needle tip of a syringe containing the spinning dope. Other spinnerets can include conducting metal wires, orifices in metal plates, or metal tips. In all cases, the applied electrical potential provides enough field strength such that a small solution volume forming at the end of the spinneret can form a Taylor cone as shown in FIGS. 3 and 4. Eventually the electric field generated by the applied potential and the small tip (spinneret) provides sufficient force to overcome the surface tension of the Taylor cone, and a polymer jet (wet fiber) is formed. By applying the electrical potential between the spinneret and the collector, the fiber is pulled toward the collector by electrostatics.

Hence, in embodiments, the method of the invention comprises at step B′), feeding the spinning dope to a spinneret while applying an electrical potential to the spinneret relative to a collector such that a jet of spinning dope forms and is collected as a nanowire on the collector.

The conditions under which electrospinning is carried out at step B′) will depend on the characteristics of the desired nanowire. Such conditions include the spinning dope flow rate, the relative difference in the electrical potential between the spinneret and the collector, the size of the nozzle of the spinneret, the temperature, the relative humidity of the environment, the spinneret-collector distance (which is referred to as the working distance), as well as the configuration of the collector. These conditions and their impact on the produced electrospun fibers are well-known to skilled persons. It is noted that nozzles with larger gages can handle more viscous dope and thus produce nanowires with larger diameter. We also note that the mechanical stretching force created by the electric field and the rotating collector helps to align the carbon nanotube and prevent agglomeration.

### In Embodiments, the Electrospinning Conditions May be as Follow:

spinneret: hollow stainless steel needle with diameter 0.361 mm (27 g)
flow rate of 1 mL/h,
electrically grounded rotating cylindrical collector (diameter of 7.5 cm) with a rotation speed of 400 rpm,
working distance: 20 cm, and/or
electric field of 1.25×10⁵ V/m applied between the needle and the collector using a high voltage power supply.

### Step B″)—Blowspinning

Blowspinning is similar to electrospinning, but eliminates the electric field. Instead, gas (typically air) is blown along the outside of the nozzle (emitter), thereby “blowing” the fiber and pulling it out of the nozzle. Electrospinning and blowspinning are compared in FIG. 4. This method, first described by Medeiros et al. (JAPS, 2009), extrudes the polymer solution through a coaxial needle whereby the polymer solution is pumped through an inner nozzle while a constant high pressure gas flow is sustained through an outer nozzle that surrounds the inner nozzle. The fiber is therefore extruded and mechanically stretched, without requiring an electric field. In principle, the needle can be made of any material and have a wide range of diameter (e.g., about 0.2 to about 2 mm)

Advantageously, as shown in Example 4, blowspinning allows producing larger quantities of fibers (squared meters) as well as very longer fibers (several meters long).

Hence, in embodiments, the method of the invention comprises at step B″), feeding the spinning dope to an inner nozzle of a spinneret while feeding pressurized gas to an outer nozzle of the spinneret such that a jet of spinning dope forms and is collected as a nanowire on a collector. In such embodiments, the inner nozzle and the outer nozzle are coaxial.

The conditions under which blowspinning is carried out at step B″) will depend on the characteristics of the desired nanowire. Such conditions include the spinning dope flow rate, air flow, the size of the inner nozzle and outer nozzle of the spinneret, the temperature, the relative humidity of the environment, the spinneret-collector distance (which is referred to as the working distance), as well as the configuration of the collector. These conditions and their impact on the produced blowspun fibers are well-known to skilled persons. It is noted that nozzles with larger gages can handle more viscous dope and thus produce nanowires with larger diameter. We also note that the mechanical stretching force created by the air flow and the rotating collector helps to align the carbon nanotube and prevent agglomeration.

### In Embodiments, the Blow Spinning Conditions May be as Follow:

spinneret: hollow needle with diameter 0.361 mm (27 g)
spinning dope flow rate of 33 μL/min,
compressed air was delivered at a constant pressure of 140 kPa, and/or
working distance: 20 cm.

### Piezoelectric Transducer

In a related aspect of the invention, there is also provided a piezoelectric transducer comprising a nanowire as described above and an electrically conductive sheath surrounding the nanowire, wherein the dielectric polymer in the electrically insulating sheath is a piezoelectric polymer and the carbon nanotube is a metallic carbon nanotube.

In embodiments, the piezoelectric polymer is polyvinylidene fluoride (PVDF), poly(I-lactic acid) (PLA) or their copolymers. In preferred embodiments, the piezoelectric polymer is PVDF.

Indeed, spinning PVDF (as when manufacturing the nanowire and the transducer of the invention) cause the crystallization of the PVDF in the orthorhombic piezoelectric β phase with the direction perpendicular to the length of the fiber (i.e., perpendicular to the longitudinal axis of the transducer). This implies that the piezoelectric polarization is perpendicular to the length of the fiber. This is in stark contrast with the random orientation of the fibers relative to the collector or target observed in the prior art, which largely negates the material property improvement obtained by nanostructuring the PVDF. Indeed, the crystalline orientation of the β phase induced in PVDF spun fibers is such that the greatest piezoelectric polarization will be radially toward (or away from) the center of the fiber. This is confirmed in FIG. 5, showing the dominance of PVDF β (200), which is in the direction perpendicular to the length of the fiber.

The transducer of the invention has thus an ideal geometry for leveraging the piezoelectric effect. This geometry consists of a radially symmetric coaxial structure in which the conductive core act as an inner central electrode and is enrobed by the insulating sheath (e.g., PVDF), which is in turn is enrobed by the conductive sheath, which acts as an outer electrode. This structure can then be used as an arbitrarily long piezoelectric PVDF nanodevice. This coaxial structure is shown in FIG. 6.

The transducer of the invention was shown in Example 2 to reversibly operate as a sensor (direct piezoelectric effect) and an actuator (inverse piezoelectric effect) without requiring any pre-poling. Regarding the direct piezoelectric effect, the effective piezoelectric voltage coefficient (g_{eff}) of the device was found to be g_{eff}=0.22 V·m·N⁻¹. Although no pre-poling was performed, this effective device value compares favorably with those reported in the literature for high-quality pure, fully poled, bulk PVDF films (g₃₃=0.14˜0.3 V·m·N⁻¹) [2-7, 2-33]. Regarding the inverse piezoelectric effect, the displacement of the fibers closely followed the form of the excitation signal and resulted in a maximum strain greater than 0.6%. The effective piezoelectric coefficient (deft) of the flexible device was estimated as 2.9 pC/N. This compares to quasi-static values of d₃₃=10˜30 pC/N reported in the literature for high-quality pure, fully poled, bulk PVDF films [2-9, 2-11].

In embodiments, the piezoelectric transducer are about ten times thinner than spider silk (which is ˜1 μm diameter).

In embodiments, the biocompatibility, chemical inertness, and mechanical flexibility that PVDF is known for, combined with the unusually long coaxial nanofiber form factor, suggests a wide range of exciting novel applications.

In addition, multiple fibers/strands were braided together to create a thicker “cord” consisting of multiple, independent transducers (they could also be otherwise woven together into a “smart membrane”). For example, with the appropriate choice of conducting sheaths, these nanofiber transducers could be integrated into smart textiles, form artificial skin or muscles, be embedded into aerospace composites, or incorporated into biomedical implants.

In addition, given that PVDF is known to have ferroelectric and pyroelectric properties, non-volatile memory or temperature-sensing applications can also be envisioned.

This approach finally enables a new form factor for piezoelectric transducers that has so far eluded practical application: a flexible, arbitrarily long, weavable, piezoelectric nanofiber, ten times thinner than spider silk, with a wide range of potential uses ranging from artificial skin and muscles, over smart textiles, to aerospace composites and biomedical implants. The easily obtained piezoelectric transducer has great sensitivity and unlike traditional, bulk, piezoelectric devices, often-difficult pre-poling was found to be completely unnecessary.

In embodiment, the electrically insulating sheath further comprises a piezoelectric ceramic, preferably as nanoparticles, dispersed in a matrix of the piezoelectric polymer. Non-limiting examples of piezoelectric ceramics include barium titanate, lead zirconium titanate, barium strontium titanate, lithium niobate, and aluminum nitride.

The transducer has an average diameter that varies between about 29 nm and about 450 nm and most preferably the average diameter is about 80 nm.

In their broad embodiments, the average diameter of the core and the thickness of the electrically insulating sheath are as described in the previous sections.

In preferred embodiments, the average diameter of the core is between about 5 nm and about 50 nm and most preferably is about 10 nm.

In preferred embodiments, the thickness of the electrically insulating sheath varies between about 10 nm and 100 nm and most preferably is about 30 nm.

In preferred embodiments, the thickness of the electrically conducting sheath varies between about 2 nm and about 100 nm and most preferably is about 5 nm.

In embodiments, the electrically conducting sheath is made of a conducting metal, such as copper, silver, palladium, platinum, iridium, graphite, graphene, aluminum, titanium, gold, and their alloys or composites. Preferably, the conducting metal is gold and its alloys and composites. Most preferably, the conducting metal is gold.

In preferred embodiments in which the piezoelectric polymer is PVDF, the PVDF is preferably at least about 10% crystalline, preferably at least about 20% crystalline, more preferably at least about 30% crystalline, yet more preferably at least about 40% crystalline, and most preferably at least about 50% crystalline. In embodiments, the PVDF is about 50% crystalline.

Also, the PVDF has preferably a crystalline volume fraction of crystalline β phase of at least about 10%, preferably at least about 20%, more preferably at least about 30%, yet more preferably at least about 40%, and most preferably of at least about 50% crystalline. In embodiments, crystalline volume fraction of crystalline β phase is of about 53%

Furthermore, the crystalline β phase of the PVDF is preferably oriented with a direction along the longitudinal axis of the transducer and with the direction perpendicular to the longitudinal axis of the transducer. This means that the piezoelectric dipole moment (polarization vector) is radially symmetric about the center of the transducer.

These transducers of the invention typically have a smooth surface.

### Transistor

In yet another related aspect of the invention, there is also provided a transistor comprising a nanowire as described above, wherein the carbon nanotube is a semi-conducting carbon nanotube, and wherein the nanowire is surrounded by a conductive sheath.

The nanowire, the core, the electrically insulating sheath, the nanotubes, and the dielectric polymer are as described above in regard of nanowires with the exception that the carbon nanotubes are limited to semi-conducting carbon nanotubes.

It should be noted that the dielectric polymer is not limited to the piezoelectric polymers used for transducers. Instead, all the polymers provided above in regard of nanowires can be used.

In embodiments, the transistor is ten times thinner than spider silk (which is ˜1 μm diameter).

In addition, multiple fibers/strands could be braided together to create a thicker “cord” consisting of multiple, independent transistors or else woven together into a “smart membrane”.

The transistor has an average diameter that varies between about 29 nm and about 450 nm and most preferably the average diameter is about 80 nm.

In their broad embodiments, the average diameter of the core and the thickness of the electrically insulating sheath are as described above in regard on nanowires.

In preferred embodiments, the average diameter of the core varies between about 5 nm and about 50 nm and most preferably is about 10 nm.

In preferred embodiments, the thickness of the electrically insulating sheath varies between about 10 nm and about 100 nm and most preferably is about 30 nm.

In preferred embodiments, the thickness of the electrically conducting sheath varies between about 2 nm and about 100 nm and most preferably is about 5 nm.

In embodiments, the electrically conducting sheath is made of a conducting metal, such as copper, silver, palladium, platinum, iridium, graphite, graphene, aluminum, titanium, gold, and their alloys or composites. Preferably, the conducting metal is gold or an alloy or composite thereof, more preferably gold.

These transistors of the invention typically have a smooth surface.

### Method of Making the Piezoelectric Transducers and the Transistors

In a related aspect of the invention, there is provided a method for manufacturing the above piezoelectric transducers and transistors. This method comprises the following steps:
i. providing the required nanowire (described above in the section for transduces and transistors) using the method for manufacturing the nanowire described above, and
ii. covering the nanowire with the conductive sheath.

As a reminder, for transducers, the dielectric polymer in the electrically insulating sheath of the nanowire is a piezoelectric polymer and the carbon nanotubes in the nanowire are metallic carbon nanotubes. For transistors, the carbon nanotubes in the nanowire are semi-conducting carbon nanotubes (the dielectric polymer is not limited to piezoelectric polymers).

Step ii can be carried out by physical vapor deposition, sputtering, dip coating, powder coating, electrochemical deposition, painting, plasma vapor deposition, chemical bath deposition, spray painting, screen printing, or electron beam deposition. Preferably it is carried out by physical vapor deposition.

The amount of PVDF crystalline β phase (preferably for transducers, not necessary for transistors) is increased approximately five-fold as a result of the electrospinning process. This single-step electrospinning process is easily scalable and can in principle be used to readily manufacture nanofiber devices of arbitrary length. The above method should thus allow the mass production of the transducers, advantageously without pre-poling.

The transducers and transistors thus produced can of course be bundled for use. For example, a plurality of transducers or transistors can be cut to a same length, assembled in a bundle, and their exposed ends can be joined with a conducting material (e.g., a silver paint) to electrically connect the cores together. The outer conducting sheaths covering the exterior of the transducers naturally make electrical contact with each other.

### Definitions

The use of the terms “a” and “an” and “the” and similar referents in the context of describing the invention (especially in the context of the following claims) are to be construed to cover both the singular and the plural, unless otherwise indicated herein or clearly contradicted by context.

The terms “comprising”, “having”, “including”, and “containing” are to be construed as open-ended terms (i.e., meaning “including, but not limited to”) unless otherwise noted. In contrast, the phrase “consisting of” excludes any unspecified element, step, ingredient, or the like. The phrase “consisting essentially of” limits the scope to the specified materials or steps and those that do not materially affect the basic and novel characteristic(s) of the invention.

Recitation of ranges of values herein are merely intended to serve as a shorthand method of referring individually to each separate value falling within the range, unless otherwise indicated herein, and each separate value is incorporated into the specification as if it were individually recited herein. All subsets of values within the ranges are also incorporated into the specification as if they were individually recited herein.

All methods described herein can be performed in any suitable order unless otherwise indicated herein or otherwise clearly contradicted by context.

The use of any and all examples, or exemplary language (e.g., “such as”) provided herein, is intended merely to better illuminate the invention and does not pose a limitation on the scope of the invention unless otherwise claimed.

No language in the specification should be construed as indicating any non-claimed element as essential to the practice of the invention.

Herein, the term “about” has its ordinary meaning. In embodiments, it may mean plus or minus 10% or plus or minus 5% of the numerical value qualified.

Unless otherwise defined, all technical and scientific terms used herein have the same meaning as commonly understood by one of ordinary skill in the art to which this invention belongs.

Other objects, advantages and features of the present invention will become more apparent upon reading of the following non-restrictive description of specific embodiments thereof, given by way of example only with reference to the accompanying drawings.

### DESCRIPTION OF ILLUSTRATIVE EMBODIMENTS

The present invention is illustrated in further details by the following non-limiting examples.

### Example 1—Self-Assembly of Carbon Nanotubes into Long, Electrically Conductive, Coaxially-Insulated Nanowires

Herein, we present a fully scalable, single-step self-assembly manufacturing approach, using electrospinning, which enables the mass-production of carbon nanotubes arranged continuously end-to-end into an electrically conducting coaxial nanowire protected by an electrically insulating sheath of chemically inert and biocompatible fluoropolymer.

### EXPERIMENTAL SECTION

Polyvinylidene fluoride (PVDF) fluoropolymer powder (Kynar 741) was obtained from Arkema and used as received. PVDF was selected as a model fluoropolymer due to its high dielectric constant¹⁻¹⁸, resistance to electrical breakdown¹⁻¹⁹, chemical inertness¹⁻²⁰, and proven biocompatibility^{1-21, 1-22}. Multi-wall carbon nanotubes (MWCNTs) were purchased from Nanocyl with an average length of 1.5 μm, an average diameter of 9.5 nm and a specific surface area of 250-300 m²/g (product no. NC7000). These MWCNTs were selected due to their metallic nature. Solutions with varying fluoropolymer (10% to 30%) and MWCNTs (0% to 1%) concentrations were prepared as follows: MWCNTs were dispersed in a 7:3 mixture (by weight) of n,n-dimethylformamide (DMF) and acetone using a Qsonica Q700 ultrasonic probe. Using too high a concentration of fluoropolymer (about 20%) or MWCNTs (about 1%) increased the viscosity of the spinning dope too much, making electrospinning impossible. Using too low a concentration of fluoropolymer (less than about 10%) resulted in failure to obtain continuous nanofibers; using too low a concentration of MWCNTs (less than about 0.4%) resulted in failure to percolate and thereby preventing the formation of a continuous conducting core. PVDF powder was gradually added to this mixture while stirring at 40° C. until a homogeneous solution was obtained. A PVDF concentration of 15.0% wt. resulted in nanofibers having a diameter of about 100 nm, while higher concentrations yielded thicker nanofibers and lower concentrations yielded thinner nanofibers. This solution was extruded through a hollow stainless steel needle with diameter 0.361 mm (27 g) at a flow rate of 1 mL/h. An electrically grounded rotating cylindrical collector (diameter of 7.5 cm) with a rotation speed of 400 rpm was placed 20 cm from the needle to align fibers. An electric field of 1.25×10⁵ V/m was applied between the metallic needle and the collector using a high voltage power supply (SL40*50, Spellman).

### Results and Discussion

A Hitachi SU-8230 scanning electron microscope (SEM) was used to study the nanowires obtained.

FIG. 7 shows a representative SEM image of nanowires sputtered with platinum to prevent surface charging artefacts. The electrospinning technique produces high quality smooth nanowires with an average diameter of about 100 nm (calculated using statistical image analysis performed with ImageJ image processing software) when a PVDF concentration of 15.0% was used. The fibers are predominantly textured in the direction of rotation of the collector, as expected. Fiber morphology and diameter was consistent regardless of MWCNT concentration.

In order to understand the electrical conductivity of the nanowires, measurements were performed according to ASTM-D4496: “Standard Test Method for D-C Resistance or Conductance of Moderately Conductive Materials”¹⁻²³ using a Keysight E4990A impedance analyzer. Square samples of (10×10) mm² in area and 0.2 mm in thickness were prepared and used to measure the average electrical conductivity. In particular, the average surface conductivity and the average conductivity of the nanowire cores were measured as shown in FIGS. 8 and 9 using silver paste contact strips. The contact strips for the average surface conductivity measurements were made by applying silver paste across the fibers, then measuring the conductivity between two contact strips. The contact strips for the average core conductivity measurements were made by applying silver paste across a cross-section exposing the core of the nanowires.

FIG. 10 shows the average electrical conductivity of the nanowires as a function of MWCNTs % wt. fraction. The average electrical conductivity of the nanowire surfaces and cores are equally low at around 10⁻¹⁵ S/cm when the concentration of MWCNTs is ≤0.4% wt. This indicates that any MWCNT present in the nanowires do not provide a continuous conductive pathway and the nanowires are therefore electrically insulating throughout the thickness of the nanowires.

However, once the MWCNT concentration reaches at least 0.5% wt., the average core conductivity of the nanowires increases by over 10 orders of magnitude to around 10⁻⁴ S/cm. At the same time, the average surface conductivity remains unchanged. This confirms that when the MWCNT concentration exceeds this percolation threshold of around 0.5% wt., continuous electrically conductive pathways along the nanowire cores form. Simultaneously, these electrically conductive cores are enrobed by an insulating sheath, as confirmed by the consistently low average surface conductivity.

In order to better understand the structure of the nanowires, transmission electron microscopy (TEM) was performed using a Thermo Scientific Talos F200C Microscope at an accelerating voltage of 200 kV. FIG. 1 shows representative TEM images of electrospun nanowires.

The TEM analysis provides the structural explanation for the electrical conductivity observations, and confirms that these are indeed long, electrically conductive, coaxially-insulated nanowires. In particular, the MWCNTs are encapsulated in the fluoropolymer and aligned along the length of the nanowires. Although the MWCNTs and fluoropolymer were mixed together and extruded using conventional electrospinning through a single needle, this core-shell morphology was obtained by self-assembly. The dielectric fluoropolymer coaxially insulates the MWCNTs from the environment and thereby prevents a short-circuit from forming during the electrospinning process which would cause the fabrication process to collapse. The mechanical stretching force created by the electric field and the rotating collector helps to align the MWCNTs and prevents agglomeration.

The self-assembled formation of the coaxial nanowire structure was achieved by manipulating the thermodynamic driving forces during formation of the wet fiber while ensuring adequate reaction kinetics are maintained during solidification. This requires appropriately selecting the nanowire components (fluoropolymer and MWCNTs) such that the relative surface energies are carefully balanced with the mechanical extension force imposed by the electrostatic attraction between the spinneret and the collector. The surface energy γ consists of the sum of the dispersive (non-polar) γ^{d} contribution and polar γ^{p} contribution, as shown in Table 1-1 for the preferred embodiment. In addition, the rate of solvent evaporation (determined by relative humidity, temperature, and solvent composition) and suspension viscosity (determined by component concentration and solvent composition) during wet fiber flight must be controlled such that the solidification into a dry nanofiber provides for sufficient time for the components to segregate into the desired coaxial structure, including alignment and percolation of MWCNTs, while allowing for adequate molecular mobility so that the nucleation and growth of the fluoropolymer sheath can occur.

TABLE 1-1
Surface energy γ of PVDF and MWCNT including
the dispersive and polar contributions.

| | | | | | | |
|---|---|---|---|---|---|---|
| Material | γ [mN m⁻¹] | = | γ^{d}[mN m⁻¹] | + | γ^{p} [mN m⁻¹] | Ref |

| | | | | |
|---|---|---|---|---|
| PVDF | 30.3 | 23.2 | 7.1 | 1-24, |
| | | | | 1-25 |
| MWCNT | 45.3 | 18.4 | 26.9 | 1-26 |

The higher total surface energy of the MWCNTs means that there is a strong thermodynamic driving force preventing the MWCNTs from migrating to the surface of the nanowires. In addition, the relatively high surface energy of the MWCNTs encourages percolation and therefore allows for the formation of a conductive core. This suggests that a wide range of fluoropolymers or other low-surface energy dielectric polymers can also be used as an insulating sheath to produce MWCNT coaxial nanowires using the electrospinning method. The MWCNTs can similarly be replaced by any choice of SWCNTs, as long as the total surface energy remains sufficiently above that of the low-surface energy dielectric polymer selected.

### Conclusions

We have shown that electrospinning offers a fully scalable, single-step manufacturing process that enables the mass-production of multiwall carbon nanotubes self-assembled continuously end-to-end into an electrically conducting coaxial nanowire protected by an electrically insulating sheath of chemically inert and biocompatible fluoropolymer. TEM observations confirm that the MWCNTs align in the direction of the nanowire axis and form a conductive network. The use of a polymer with a low surface energy, such as PVDF, helps enrobe the MWCNTs in a protective sheath, thereby resolving the problem of electrospinnability of MWCNT. This nanometric self-assembled structure is a particularly promising solution for replacing copper vias and interconnects in today's Very-Large-Scale Integration (VLSI) electronic circuits, as well as use in novel flexible electronics, including biomedical applications. The produced nanowires offer the elusive promise of finally employing the exciting properties of individual MWCNTs at the industrial scale while mitigating the known biotoxicity of MWCNTs.

### Example 2—Self-Assembly of Polyvinylidene Fluoride (PVDF) and Carbon Nanotubes into Flexible Piezoelectric Nanowire Transducers

### Abstract

We report on a novel piezoelectric nanowire transducer design based on the polymer polyvinylidene fluoride (PVDF) obtained by a scalable self-assembly electrospinning process. This process produces arbitrarily long 80 nm diameter coaxial nanowires of predominantly crystalline β-phase PVDF oriented along the length of the fiber with integrated carbon nanotube inner electrodes. The device obtained was shown to reversibly operate as a sensor (direct piezoelectric effect) and an actuator (inverse piezoelectric effect) without requiring any pre-poling. This approach finally enables a new form factor for piezoelectric devices that has so far eluded practical application: a flexible, arbitrarily long, weavable, piezoelectric nanowire, ten times thinner than spider silk, with a wide range of potential uses ranging from artificial skin and muscles, over smart textiles, to aerospace composites and biomedical implants.

### Introduction

We report on how leveraging the interfacial tension between carbon nanotubes and PVDF can result in the self-assembly of a long, continuous, flexible, piezoelectric nanowire device using a scalable electrospinning process. The self-assembled piezoelectric device thus obtained is demonstrated to work reversibly as both a sensor and an actuator, thereby enabling a wide range of novel applications.

### Sample Preparation

Polyvinylidene fluoride (PVDF) powder (Arkema Kynar 741) was used as-received. Multi-wall carbon nanotubes (MWCNTs) with an average length of 1.5 μm, an average diameter of 9.5 nm and a specific surface area of 250-300 m²/g were also used as-received (Nanocyl product no. NC7000). These MWCNTs were selected due to their metallic nature. 0.6% wt. MWCNTs were dispersed in a 7:3 mixture (by weight) of n,n-dimethylformamide (DMF) and acetone using a Qsonica Q700 ultrasonic probe. 14.4% wt. PVDF powder was gradually dissolved into this mixture while stirring at 40° C. until a homogeneous solution was obtained. This solution was extruded through a hollow stainless steel needle with diameter of 0.361 mm (27 g) at a flow rate of 1 mL/h. An electrically grounded rotating cylindrical collector (diameter of 7.5 cm) with a rotation speed of 400 rpm was placed 20 cm from the needle to align fibers. An electric field of 1.25×10⁵ V/m was applied between the metallic needle and the collector using a high voltage power supply (SL40*50, Spellman). The nanowires obtained by this electrospinning process were then coated with gold using physical vapor deposition (PVD).

### Structural Characterization and Discussion

The nanowires obtained by electrospinning were observed using a Hitachi SU-8230 scanning electron microscope (SEM). FIG. 11 is a representative SEM image showing the smooth nanowires with an average diameter of approximately 80 nm (obtained using 14.4% wt. PVDF solution).

A Thermo Scientific Talos F200C transmission electron microscope (TEM) was used at an accelerating voltage of 200 kV to further study the obtained nanostructures. FIG. 12 is a representative TEM image of PVDF/MWCNTs electrospun nanowires showing that MWCNTs form the core of the nanowire, and are completely enrobed by PVDF. The relatively low surface tension of PVDF (30.3 mN m⁻¹ [2-24; 2-25]) compared to the relatively high surface tension of MWCNTs (45.3 mN m⁻¹ [2-26]) is a likely explanation for the self-assembly of this coaxial nanostructure.

Having characterized the geometry and structure of the nanowires with SEM and TEM, X-ray diffraction (XRD) was further employed to study the crystalline structure of PVDF. A Panalytical X'pert Pro MPD X-ray diffractometer using Cu—K_{α} radiation λ=1.54 Å was used at room temperature. FIG. 5 shows a representative X-ray diffractogram of as-received PVDF virgin powder and electrospun PVDF/MWCNTs nanowires. All diffracted peaks were fitted to Voigt functions, and the relative volume fractions of crystalline phases were quantified using structure factor calculations (Table 1).

TABLE 1
Diameter, degree of crystallinity, and phase volume
fractions in PVDF virgin powder and nanowires.

| | PVDF Virgin | MWCNTs/PVDF |
|---|---|---|
| | Powder | nanowires |
| Fiber diameter (nm) | n/a | 80 |
| Degree of crystallinity (%) | 40 | 52 |
| Crystalline volume fraction % α | 89 | 47 |
| phase (not piezoelectric) | | |
| Crystalline volume fraction % β | 11 | 53 |
| phase (piezoelectric) | | |

The crystal structure of the non-piezoelectric α phase is monoclinic [2-27, 2-28], while the structure of the piezoelectric β phase is orthorhombic [2-29]. The as-received PVDF virgin powder is only 40% crystalline and consists primarily of the non-piezoelectric α phase. The coaxial PVDF/MWCNTs nanowires have greater PVDF crystallinity (52%), in which the piezoelectric β phase dominates (53%). The net effect is that the amount of β phase increased approximately five-fold as a result of the electrospinning process. These results are in-line with those obtained in the past using similar electrospinning process parameters in the absence of MWCNTs [2-23]; this suggests that the incorporation of MWCNTs does not have a measurable effect on the crystalline structure of PVDF.

It is worth noting the absence of a peak at 2θ=35.04° for the nanowires in FIG. 5, which would correspond to the β phase (001) plane. This indicates that the crystallographic direction runs along the length of the fiber axis, thereby confirming that the molecular chains of the β phase are oriented along the length of the fiber axis [2-23, 2-30 to 2-32]. The strong (200) peak confirms that the or direction is therefore perpendicular to the fiber length, consistent with a piezoelectric dipole moment (polarization vector) that is radially symmetric about the center of the fiber, as hypothesized in FIG. 6.

### Piezoelectric Behavior

Approximately 10,000 single nanowires were simultaneously measured to obtain an average characterization, as illustrated in FIG. 13. In this assembly, a 15 mm width of parallel nanowires were cross-sectioned with a scalpel to a length of 15 mm. The exposed ends were then painted with silver paste to electrically connect to all the embedded MWCNT inner electrodes simultaneously. The gold outer electrodes covering the exterior of the fibers naturally made electrical contact with each other. Copper wire probes were used to then measure (or apply) a voltage between the nanowire inner electrodes and outer electrodes.

### Direct Piezoelectric Effect (Sensor Mode)

### The Direct Piezoelectric Effect is Given by the Equation:

$${E}_{i} = {g}_{iJ} {σ}_{J} ( i = \{ 1 , 2 , 3 \} ; J = \{ 1 , 2 , … , 6 \} ) \qquad ( 1 )$$

Where Eᵢ is the electric field in the i direction, σⱼ is the mechanical stress in the J direction, and gᵢⱼ is the piezoelectric voltage coefficient.

A cyclic uniaxial compressive stress of 31 kPa at a frequency of 2 Hz was uniformly applied onto the assembly of parallel fibers (an area of 15 mm×15 mm) using a vibration exciter K2007E01 (FIG. 13). A Keysight DSOX3014T oscilloscope was used to record the output voltage generated between inner and outer electrodes of the nanowire assembly (FIG. 13).

FIG. 14 illustrates the direct piezoelectric effect of the device. An electric field of up to 6.9×10⁷ V/m was generated by applying a mechanical stress of about 31 kPa. The negative values of the electric field correspond to the relaxation of the fibers upon removing the applied mechanical stress (spring-back). Using equation 1, the effective piezoelectric voltage coefficient (g_{eff}) of the flexible device was found to be g_{eff}=0.22 V·m·N⁻¹. Although no pre-poling was performed, this effective device value compares favorably with those reported in the literature for high-quality pure, fully poled, bulk PVDF films (g₃₃=0.14˜0.3 V·m·N⁻¹) [2-7, 2-33].

### Inverse Piezoelectric Effect (Actuator Mode)

### As Piezoelectricity is Reversible, the Inverse Piezoelectric Effect is Given by the Equation:

$${ε}_{J} = {d}_{Ji} {E}_{i} ( i = \{ 1 , 2 , 3 \} ; J = \{ 1 , 2 , … , 6 \} ) \qquad ( 2 )$$

Where εj is the strain along J, Eᵢ is the applied electric field along i, and dⱼᵢ is the piezoelectric coefficient.

Laser scanning vibrometry (LSV) was used to directly measure the displacement of the nanowire when electrically excited. The measurement was carried out using a PolyTech GmbH (Germany) OVF-505 laser beam connected to an OVF-2570 vibrometer. The laser beam was perpendicular to the fiber lengths. An electrical signal with maximum amplitude 5×10⁹ V/m at a frequency of 35 kHz was applied to excite the piezoelectric device. FIG. 15 shows the applied electric field and the resulting mechanical strain. The displacement of the fibers closely followed the form of the excitation signal and resulted in a maximum strain greater than 0.6%.

The effective piezoelectric coefficient (d_{eff}) of the flexible device was estimated using equation (2) and a value of d_{eff}=2.9 pC/N was obtained. This compares to quasi-static values of d₃₃=10˜30 pC/N reported in the literature for high-quality pure, fully poled, bulk PVDF films [2-9, 2-11]. The obtained d_{eff} is slightly lower than that reported in the literature, likely due to the dynamic excitation of the transducers-indeed, there is a small ˜0.3×10⁻⁴ s response lag between the excitation and the induced strain.

### Conclusion

A piezoelectric PVDF polymer nanowire transducer with integrated electrodes was manufactured using the electrospinning process. The self-assembly of MWCNTs forms a continuous inner electrode at the core of the 80 nm diameter fibers, thereby leveraging the PVDF nanostructure. This single-step electrospinning process is easily scalable and can in principle be used to readily manufacture nanowire devices of arbitrary length. Upon applying an outer electrode, the completed piezoelectric device was shown to operate reversibly as a sensor (direct effect) and actuator (inverse effect). The easily obtained nanostructure allows for a piezoelectric transducer with great sensitivity to be mass-produced. Unlike traditional, bulk, piezoelectric devices, the often difficult pre-poling was found to be completely unnecessary.

The thus obtained nanowires are ten times thinner than spider silk (˜1 μm diameter). The biocompatibility, chemical inertness, and mechanical flexibility that PVDF is known for, combined with the unusually long coaxial nanowire form factor, suggests a wide range of exciting novel applications. In addition, multiple fibers/strands could be braided together to create a thicker “cord” consisting of multiple, independent transducers or else woven together into a “smart membrane”. For example, with the appropriate choice of outer electrodes, these nanowire transducers could be integrated into smart textiles, form artificial skin or muscles, be embedded into aerospace composites, or incorporated into biomedical implants. In addition, given that PVDF is known to have ferroelectric and pyroelectric properties, non-volatile memory or temperature-sensing applications can also be envisioned.

### Example 3—Effect of MWCNTs Dispersion Time on Fiber Conductivity

We prepared and electrospun a spinning dope as per Example 1 using various dispersion times for dispersing the MWCNTs in the 7:3 mixture (by weight) of n,n-dimethylformamide and acetone. The MWCNTs concentration was 2% w/w. The PVDF concentration as 18% w/w. The dispersion time were 0.5 h, 1 h, 5 h, and 10 h. The conductivity of the resulting fibers' cores and surface was measured using the method reported in Example 1 and FIGS. 8 and 9.

FIG. 16 clearly shows that the dispersion time 0.5 h produced fibers with low core conductivity. A dispersion time of 1 h yielded much better core conductivity and a dispersion time of 5 h yielded the highest conductivity. The dispersion time of 10 h yielded a low core conductivity similar to the 0.5 h dispersion time.

### Example 4—Using Blowspinning Instead of Electrospinning

We prepared and blowspun a spinning dope as per Examples 1 and 2. The solvent was a 7:3 mixture (by weight) of n,n-dimethylformamide and acetone. The MWCNTs concentration was 2% w/w. The PVDF concentration as 18% w/w. The dispersion time was 5 h.

Additional details on the apparatus, including drawings and nozzle schematics, can be found in Medeiros et al. 2009. The polymeric solution was injected through the inner nozzle with a flow rate of 33 μL/min. Compressed air was delivered at a constant pressure of 140 kPa through the outer nozzle. All tests were performed at room temperature, and the distance between the emitter and the collector was held constant at 20 cm.

It is well known that blowspinning can produce fibers at 5-10× the rate of electrospinning. Indeed, large quantities of very long fibers were obtained as shown in the picture presented in FIG. 17.

The scope of the claims should not be limited by the preferred embodiments set forth in the examples, but should be given the broadest interpretation consistent with the description as a whole.

### REFERENCES

The present description refers to a number of documents, the content of which is herein incorporated by reference in their entirety. These documents include, but are not limited to, the following:
1-1 Dresselhaus, M. S. Down the straight and narrow. Nature 358, 195-196 (1992).
1-2 Hamada, N., Sawada, S. & Oshiyama, A. New one-dimensional conductors: Graphitic microtubules. Physical review letters 68, 1579-1581, doi: 10.1103/PhysRevLett.68.1579 (1992).
1-3 LORENTS, R. S. R. a. D. C. MECHANICAL AND THERMAL PROPERTIES OF CARBON NANOTUBES. Carbon 33, 925-930 (1995).
1-4 Seunghun Hong, S. M. A flexible approach to mobility. Nature nanotechnology 2, 207-208 (2007).
1-5 Teri Wang Odom, J. L. H., Philip Kim and Charles M. Lieber. Atomic structure and electronic properties of single walled carbon nanotubes. Nature 391, 62-64 (1998).
1-6 INTERNATIONAL ROADMAP FOR DEVICES AND SYSTEMS, International Roadmap Committee (IRC). (2016).
1-7 Berger, C., Poncharal, P., Yi, Y. & de Heer, W. Ballistic conduction in multiwalled carbon nanotubes. J Nanosci Nanotechnol 3, 171-177, doi:10.1166/jnn.2003.180 (2003).
1-8 C. T. White, T. N. T. Carbon nanotubes as long ballistic conductors. Nature 393, 340-342 (1998).
1-9 Philippe Poncharal, C. B., Yan Yi Z. L. Wang, Walt A. de Heer. Room temperature ballistic conduction in carbon nanotubes. The Journal of Physical Chemistry B 106, 12104-12118 (2002).
1-10 Raychowdhury, A. & Roy, K. Modeling of metallic carbon-nanotube interconnects for circuit simulations and a comparison with Cu interconnects for scaled technologies. IEEE Transactions on Computer-Aided Design of Integrated Circuits and Systems 25, 58-65, doi: 10.1109/tcad.2005.853702 (2006).
1-11 Wei, B. Q., Vajtai, R. & Ajayan, P. M. Reliability and current carrying capacity of carbon nanotubes. Applied Physics Letters 79, 1172-1174, doi: 10.1063/1.1396632 (2001).
1-12 Y. Ando, X. Z., H. Shimoyama, G. Sakai, K. Kaneto. Physical properties of MWCNTs. International Journal of Inorganic Materials 1, 77-82 (1999).
1-13 Aida Todri-Sanial, J. D., Antonio Maffucci. Carbon Nanotubes for Interconnects Process, Design and Applications. (2017).
1-14 F. Kreupl, A. P. G., G. S. Duesberg, W. Steinhogl, M. Liebau, E. Unger, W. Honlein. Carbon nanotubes in interconnect applications. Microelectronic Engineering 64, 399-408 (2002).
1-15 Vanpaemel, J. et al. Growth and integration challenges for carbon nanotube interconnects. Microelectronic Engineering 120, 188-193, doi: 10.1016/j.mee.2013.09.015 (2014).
1-16 Formhals, A. Process and Apparatus for Preparing Artificial Threads, U.S. Pat. No. 1,975,504. (1934).
1-17 Subbiah, T., Bhat, G. S., Tock, R. W., Parameswaran, S. & Ramkumar, S. S. Electrospinning of nanofibers. Journal of Applied Polymer Science 96, 557-569, doi: 10.1002/app.21481 (2005).
1-18 Junichi Sako, S. M. T., Ibaraki; Shoji Kawachi, Amagasaki; Toshiharu Yagi. POLYMERIC DIELECTRIC FOR CAPACITORS AND THE LIKE CONSISTING ESSENTIALLY OF A WNY DENE FLUORIDE-TRIFLUOROETHYLENE COPOLYMER, 4,173,033. (Oct. 30, 1979).
1-19 Jow, T. R. & Cygan, P. J. Dielectric breakdown of polyvinylidene fluoride and its comparisons with other polymers. Journal of Applied Physics 73, 5147-5151, doi: 10.1063/1.353789 (1993).
1-20 Liu, F., Hashim, N. A., Liu, Y., Abed, M. R. M. & Li, K. Progress in the production and modification of PVDF membranes. Journal of Membrane Science 375, 1-27, doi: 10.1016/j.memsci.2011.03.014 (2011).
1-21 Gaetan Laroche, Y. M., Robert Guidoin, Martin W. King, Louisette Martin, Thien H O W, and Yvan Douville. Polyvinylidene fluoride (PVDF) as a biomaterial: From polymeric raw material to monofilament vascular suture. Journal of Biomedical Materials Research 29, 1525-1536 (1995).
1-22 U. Klingea, B. K., A. P. Ottinger. K. Jungea, V. Schumpelick. PVDF as a new polymer for the construction of surgical meshes. Biomaterials 23, 3487-3493 (2002).
1-23 ASTM INTERNATIONAL. Standard Test Method D4496 (West Conshohocken, 2013).
1-24 Wendt, D. K. O. R. C. Estimation of the surface free energy of polymers. JOURNAL OF APPLIED POLYMER SCIENCE 13, 1741-1747 (1969).
1-25 Wu, S. Calculation of interfacial tension in polymer systems. Journal of Polymer Science Part C 34, 19-30 (1971).
1-26 Nuriel, S., Liu, L., Barber, A. H. & Wagner, H. D. Direct measurement of multiwall nanotube surface tension. Chemical Physics Letters 404, 263-266, doi: 10.1016/j.cplett.2005.01.072 (2005).
[2-1] X. Chen, S. Xu, N. Yao, W. Xu, and Y. Shi, “Potential measurement from a single lead zirconate titanate nanofiber using a nanomanipulator,” Applied Physics Letters, vol. 94, no. 25, 2009.
[2-2] Y. Lin, Y. Liu, and H. A. Sodano, “Hydrothermal synthesis of vertically aligned lead zirconate titanate nanowire arrays,” Applied Physics Letters, vol. 95, no. 12, 2009.
[2-3] W. S. Yun, J. J. Urban, Q. Gu, and H. Park, “Ferroelectric properties of individual barium titanate nanowires investigated by scanned probe microscopy,” Nano Letters, vol. 2, no. 5, 2002.
[2-4] S. Xu, B. J. Hansen, and Z. L. Wang, “Piezoelectric-nanowire-enabled power source for driving wireless microelectronics,” Nature Communication, vol. 1, no. 93, 2010.
[2-5] G. Laroche, Y. Marois, R. Guidoin, M. W. King, L. Martin, T. How, and Y. Douville, “Polyvinylidene fluoride (PVDF) as a biomaterial: From polymeric raw material to monofilament vascular suture,” Journal of Biomedical Materials Research, vol. 29, no. 12, 1995.
[2-6] J. Sako, M. Tatemoto, S. Kawachi, T. Yagi, “Polymeric dielectric for capacitors and the like consisting essentially of a vinylidene fluoride-trifluoroethylene copolymer,” U.S. Pat. No. 4,173,033A, 1979.
[2-7] H. Kawai, “The piezoelectricity of poly(vinylidene fluoride),” Japanese Journal of Applied Physics, vol. 8, 1969.
[2-8] Y. Huang, G. Rui, Q. Li, et al., “Enhanced piezoelectricity from highly polarizable oriented amorphous fractions in biaxially oriented poly(vinylidene fluoride) with pure β crystals,” Nature Communication, vol. 12, no. 675, 2021.
[2-9] A. J. Lovinger, “Ferroelectric polymers,” Science, vol. 220, no. 4602, 1983.
[2-10] T. Wongwirat, Z. Zhu, G. Rui, R. Li, P. Laoratanakul, H. He, H. Manuspiya, and L. Zhu, “Origins of electrostriction in poly(vinylidene fluoride)-based ferroelectric polymers,” Macromolecules, vol. 53, no. 24, 2020.
[2-11] H. Ohigashi, “Electromechanical properties of polarized polyvinylidene fluoride films as studied by the piezoelectric resonance method,” Journal of Applied Physics, vol. 47, no. 3, 1976.
[2-12] B. K. U. Klingea, A. P. Ottinger. K. Jungea, V. Schumpelick, “PVDF as a new polymer for the construction of surgical meshes,” Biomaterials, vol. 23, no. 16, 2002.
[2-13] C. Chang, V. H. Tran, J. Wang, Y. K. Fuh, and L. Lin, “Direct-write piezoelectric polymeric nanogenerator with high energy conversion efficiency,” Nano Letters, vol. 10, no. 2, 2010.
[2-14] X. Lu, H. Qu, and M. Skorobogatiy, “Piezoelectric micro- and nanostructured fibers fabricated from thermoplastic nanocomposites using a fiber drawing technique: comparative study and potential applications,” ACS Nano, vol. 11, no. 2, 2017.
[2-15] Y. M. Yousry, K. Yao, S. Chen, W. H. Liew, and S. Ramakrishna, “Mechanisms for enhancing polarization orientation and piezoelectric parameters of PVDF nanofibers,” Advanced Electronic Materials, vol. 4, no. 6, 2018.
[2-16] P. Zhang, X. Zhao, X. Zhang, Y. Lai, X. Wang, J. Li, G. Wei, and Z. Su, “Electrospun doping of carbon nanotubes and platinum nanoparticles into the beta-phase polyvinylidene difluoride nanofibrous membrane for biosensor and catalysis applications,” ACS Applied Materials & Interfaces, vol. 6, no. 10, 2014.
[2-17] C. Zhao, J. Niu, Y. Zhang, C. Li, and P. Hu, “Coaxially aligned MWCNTs improve performance of electrospun P(VDF-TrFE)-based fibrous membrane applied in wearable piezoelectric nanogenerator,” Composites Part B: Engineering, vol. 178, no. 107447, 2019.
[2-18] A. Formhals, “Process and apparatus for preparing artificial threads,” U.S. patent U.S. Pat. No. 1,975,504A, 1934.
[2-19] C. Salas, “Solution electrospinning of nanofibers,” in Electrospun Nanofibers: Woodhead, 2017.
[2-20] S. Kalani, R. Kohandani, and R. Bagherzadeh, “Flexible electrospun PVDF-BaTiO₃ hybrid structure pressure sensor with enhanced efficiency,” RSC Advances, vol. 10, no. 58, 2020.
[2-21] H. Kim, F. Torres, Y. Wu, D. Villagran, Y. Lin, and T. L. Tseng, “Integrated 3D printing and corona poling process of PVDF piezoelectric films for pressure sensor application,” Smart Materials and Structures, vol. 26, no. 8, 2017.
[2-22] H. B. Lee, Y. W. Kim, J. Yoon, N. K. Lee, and S. H. Park, “3D customized and flexible tactile sensor using a piezoelectric nanofiber mat and sandwich-molded elastomer sheets,” Smart Materials and Structures, vol. 26, no. 4, 2017.
[2-23] C. M. Azzaz, L. H. C. Mattoso, N. R. Demarquette, and R. J. Zednik, “Polyvinylidene fluoride nanofibers obtained by electrospinning and blowspinning: Electrospinning enhances the piezoelectric β-phase-myth or reality?,” Journal of Applied Polymer Science, vol. 138, no. 10, 2020.
[2-24] D. K. Owens, R. C. Wendt, “Estimation of the surface free energy of polymers,” Journal of Applied Polymer Science, vol. 13, no. 8, 1969.
[2-25] S. Wu, “Calculation of interfacial tension in polymer systems,” Journal of Polymer Science Part C, vol. 34, no. 1, 1971.
[2-26] S. Nuriel, L. Liu, A. H. Barber, and H. D. Wagner, “Direct measurement of multiwall nanotube surface tension,” Chemical Physics Letters, vol. 404, no. 4-6, 2005.
[2-27] M. A. Bachmann and J. B. Lando, “A reexamination of the crystal structure of phase II of poly(vinylidene fluoride),” Macromolecules, vol. 14, no. 1, 1981.
[2-28] Y. Takahashi, Y. Matsubara, and H. Tadokoro, “Crystal structure of form II of poly(vinylidene fluoride),” Macromolecules, vol. 16, no. 10, 1983.
[2-29] R. Hasegawa, Y. Chatani, and H. Adokoro, “Crystal structures of three crystalline forms of poly(vinylidene fluoride),” Polymer Journal, vol. 3, no. 5, 1972.
[2-30] X. Ma, J. Liu, C. Ni, D. C. Martin, D. B. Chase, and J. F. Rabolt, “Molecular orientation in electrospun poly(vinylidene fluoride) fibers,” ACS Macro Letters, vol. 1, no. 3, 2012.
[2-31] M. Richard-Lacroix and C. Pellerin, “Molecular orientation in electrospun fibers: from mats to single fibers,” Macromolecules, vol. 46, no. 24, 2013.
[2-32] Z. Wang, B. Sun, X. Lu, C. Wang, and Z. Su, “Molecular orientation in individual electrospun nanofibers studied by polarized AFM-IR,” Macromolecules, vol. 52, no. 24, 2019.
[2-33] B. S. E. Venkatragavaraj, P. R. Vinod, and M. S. Vijaya, “Piezoelectric properties of ferroelectric PZT polymer composites,” Journal of Physics D: Applied Physics, vol. 34, no. 487, 2001.
Shimizu, R. N., Demarquette N. R. Evaluation of Sourface Energy of Solid Polymers Using Different Models. Journal of Applied Polymer Science 76, 1831-1845 (2000),
Wu, S. Polymer Interface and Adhesion; Marcel Dekker: New York (1982)
E. S. Medeiros, G. M. Glenn, A. P. Klamczynski, W. J. Orts, and L. H. C. Mattoso, “Solution blow spinning: A new method to produce micro- and nanofibers from polymer solutions,” Journal of Applied Polymer Science, 113, 2322-2330, (2009).

1. A nanowire comprising an electrically conducting or semi-conducting core surrounded by an electrically insulating sheath,
wherein the core comprises (preferably consists of) a plurality of carbon nanotubes and the sheath comprises (preferably consists of) a dielectric polymer,
wherein the core has an average diameter of at most about 1000 nm and the nanowire has an average diameter of at most about 10 μm, and
wherein, in the core, the carbon nanotubes are aligned along the longitudinal axis of the nanowire, and
wherein, in the core, the carbon nanotubes are in direct contact with each other without intervening dielectric polymer and thus form an uninterrupted conducting or semi-conducting electrical path along the length of the nanowire.

2. The nanowires of claim 1, wherein the carbon nanotubes are conducting carbon nanotubes

3. The nanowires of claim 2, wherein the nanowires have an average core conductivity of at least about 10⁻⁵ S/cm, preferably at least about 5×10⁻⁵ S/cm, and most preferably of about 10⁻⁴ S/cm or more.

4. The nanowires of claim 1, wherein the carbon nanotubes are semi-conducting carbon nanotubes.

5. The nanowires of any one of claims 1 to 4, wherein the carbon nanotubes are single-walled carbon nanotubes or multi-walled carbon nanotubes, preferably multi-walled carbon nanotubes.

6. The nanowires of any one of claims 1 to 5, wherein the nanowires have an average surface conductivity of less than about 10⁻¹⁰ S/cm, preferably less than about 10⁻¹² S/cm, more preferably less than about 10⁻¹⁴ S/cm, and most preferably of about 10⁻¹⁵ S/cm or less.

7. The nanowires of any one of claims 1 to 6, wherein the dielectric polymer is a dielectric polymer having a surface energy substantially lower than the surface energy of the carbon nanotubes in the core.

8. The nanowires of claim 7, wherein the surface energy of the dielectric polymer is at least about 5 mN m⁻¹ lower than the surface energy of the carbon nanotubes, preferably at least about 7.5 mN m⁻¹ lower than the surface energy of the carbon nanotubes, more preferably at least about 10 mN m⁻¹ lower than the surface energy of the carbon nanotubes, even more preferably at least about 12.5 mN m⁻¹ lower than the surface energy of the carbon nanotubes, and most preferably at least about 15 mN m⁻¹ lower than the surface energy of the carbon nanotubes.

9. The nanowires of any one of claims 1 to 8, wherein the dielectric polymer is
a fluoropolymer [such as polytetrafluoroethylene (PTFE), polyvinyl fluoride (PVF), ethylene tetrafluoroethylene (ETFE), fluorinated ethylene propylene (FEP), and polyvinylidene fluoride (PVDF)], a polyolefin [such as polyethylene, polypropylene, polybutylene], a styrenic polymer [such as polystyrene, acrylonitrile butadiene styrene, styrene butadiene styrene copolymer], a polyamide [such as polyamide-6,6, polyamide-6-10, polyamide-11], or a polyester [such as polyethylene terephthalate, polypropylene terephthalate, polybutylene terephthalate, poly(I-lactic acid)],
preferably a fluoropolymer, and
most preferably PVDF.

10. The nanowires of any one of claims 1 to 9, wherein the dielectric polymer is chemically inert and/or biocompatible, preferably both.

11. The nanowires of any one of claims 1 to 10, wherein the carbon nanotubes have an average diameter of at least about 0.4 nm, preferably at least about 1 nm, more preferably at least about 2.5 nm, yet more preferably at least about 5 nm, even more preferably at least about 7.5 nm, and most preferably at least about 10 nm.

12. The nanowires of any one of claims 1 to 11, wherein the carbon nanotubes have an average diameter of at most about 100 nm, preferably at most about 75 nm, more preferably at most about 50 nm, yet more preferably at most about 25 nm, even more preferably at most about 15 nm, and most preferably at most about 10 nm.

13. The nanowires of any one of claims 1 to 12, wherein the carbon nanotubes have an average diameter of about 10 nm.

14. The nanowires of any one of claims 1 to 13, wherein the core is made of single carbon nanotubes arranged end-to-end and not substantially overlapping each other.

15. The nanowires of any one of claims 1 to 13, wherein the core is made of bundles of carbon nanotubes, with the nanotubes are arranged end-to-end as well as side-by-side.

16. The nanowires of any one of claims 1 to 15, wherein the core has an average diameter of at least about 0.4 nm, preferably at least about 1 nm, more preferably at least about 2.5 nm, yet more preferably at least about 5 nm, even more preferably at least about 7.5 nm, and most preferably at least about 10 nm.

17. The nanowires of any one of claims 1 to 16, wherein the core has an average diameter of at most about 750 nm, preferably at most about 500 nm, more preferably at most about 250 nm, even more preferably at most about 100 nm, yet more preferably at most about 75 nm, more preferably at most about 50 nm, even more preferably at most about 25 nm, and most preferably at most about 10 nm.

18. The nanowires of any one of claims 1 to 17, wherein the core has an average diameter of about 10 nm.

19. The nanowires of any one of claims 1 to 18, wherein the insulating sheath is at least about 5 nm thick, preferably at least about 10 nm thick, more preferably at least about 15 nm thick, yet more preferably at least about 20 nm thick, even more preferably at least about 25 nm thick, more preferably at least about 30 nm thick, and most preferably at least about 35 nm thick.

20. The nanowires of any one of claims 1 to 19, wherein the insulating sheath is at most about 5 μm thick, preferably at most about 2.5 μm thick, more preferably at most about 1 μm thick, even more preferably at most about 500 nm thick, yet more preferably at most about 250 nm thick, even more preferably at most about 100 nm thick, and most preferably at most about 50 nm think.

21. The nanowires of any one of claims 1 to 20, wherein the insulating sheath is about 35 nm or about 45 nm thick.

22. The nanowires of any one of claims 1 to 21, having an average diameter of at least about 10.4 nm, preferably at least about 15 nm, preferably at least about 25 nm, preferably at least about 50 nm, preferably at least about 60 nm, preferably at least about 70 nm, and most preferably at least about 80 nm.

23. The nanowires of any one of claims 1 to 22, having an average diameter of at most about 5 μm, preferably at most about 1000 nm, more preferably at most about 500 nm, yet more preferably at most about 200 nm, even more preferably at most about 150 nm, and most preferably at most about 100 nm.

24. The nanowires of any one of claims 1 to 23, having an average diameter of about 80 nm or about 100 nm.

25. A method for manufacturing the nanowires of any one of claims 1 to 24, the method comprising:
C) providing a spinning dope comprising the dielectric polymer, the carbon nanotubes, and a solvent or a mixture thereof, and
D) spinning the spinning dope.

26. The method of claim 25, wherein the spinning dope comprises a mixture of solvents, preferably a mixture of n,n-dimethylformamide (DMF) and acetone, and most preferably a 7:3 mixture (by weight) of DMF and acetone.

27. The method of claim 25 or 26, wherein the concentration of the polymer in the spinning dope is from about 10 to about 30 w/w % and is preferably about 15 w/w %, all percentages being based on the total weight of the polymer and the solvent mixture.

28. The method of any one of claims 25 to 26, wherein the concentration of the carbon nanotubes in the spinning dope is at least about 0.5 w/w %.

29. The method of any one of claims 25 to 28, comprising:
A)_providing a spinning dope comprising the dielectric polymer, the carbon nanotubes, and a solvent or a mixture thereof, and
B′) electrospinning the spinning dope.

30. The method of claim 29, comprising at step B′), feeding the spinning dope to a spinneret while applying an electrical potential to the spinneret relative to a collector such that a jet of spinning dope forms and is collected as a nanowire on the collector.

31. The method of claim 29 or 30, wherein, at step B′), the electrospinning is carried out under one or more (preferably all) of the following conditions:
spinneret: hollow stainless steel needle with diameter 0.361 mm (27 g)
flow rate of 1 mL/h,
electrically grounded rotating cylindrical collector (diameter of 7.5 cm) with a rotation speed of 400 rpm,
working distance: 20 cm, and/or
electric field of 1.25×10⁵ V/m applied between the needle and the collector using a high voltage power supply.

32. The method of any one of claims 25 to 28, comprising:
A) providing a spinning dope comprising the dielectric polymer, the carbon nanotubes, and a solvent or a mixture thereof, and
B″) blowspinning the spinning dope.

33. The method of claim 32, comprising at step B′), feeding the spinning dope to an inner nozzle of a spinneret while feeding pressurized gas to an outer nozzle of said spinneret such that a jet of spinning dope forms and is collected as a nanowire on a collector, wherein the inner nozzle and the outer nozzle are coaxial.

34. The method of any one of claims 25 to 31, wherein, at step B), the electrospinning is carried out under one or more (preferably all) of the following conditions:
spinneret: hollow needle with diameter 0.361 mm (27 g)
spinning dope flow rate of 33 μL/min,
compressed air was delivered at a constant pressure of 140 kPa, and
working distance: 20 cm.

35. The method of claim 30 or 33, wherein the collector is planar, a rotating drum, a treadmill, a ring, or of another shape.

36. The method of claim 35, wherein the collector is static or dynamic.

37. A piezoelectric transducer comprising the nanowire of any one of claims 1 to 3 and 5 to 24 and an electrically conductive sheath surrounding the nanowire, wherein the dielectric polymer in the electrically insulating sheath is a piezoelectric polymer and the carbon nanotube is a metallic carbon nanotube.

38. The transducer of claim 37, wherein the piezoelectric polymer is polyvinylidene fluoride (PVDF), poly(I-lactic acid) (PLA) or their copolymers,

39. The transducer of claim 37 or 38, wherein the piezoelectric polymer is PVDF.

40. The transducer of claim 39, wherein the PVDF is at least about 10% crystalline, preferably at least about 20% crystalline, more preferably at least about 33% crystalline, yet more preferably at least about 40% crystalline, and most preferably at least about 50% crystalline.

41. The transducer of 40, wherein the PVDF is about 50% crystalline.

42. The transducer of any one of claims 34 to 41, wherein the PVDF has a crystalline volume fraction of crystalline β phase of at least about 10%, preferably at least about 20%, more preferably at least about 33%, yet more preferably at least about 40%, and most preferably of at least about 50% crystalline.

43. The transducer of claim 42, wherein the PVDF has a crystalline volume fraction of crystalline β phase of about 53%

44. The transducer of claim 42 or 43, wherein the crystalline β phase of the PVDF is oriented with a direction along the longitudinal axis of the transducer and with the direction perpendicular to the longitudinal axis of the transducer.

45. The transducer of any one of claims 37 to 44, wherein the electrically insulating sheath further comprises a piezoelectric ceramic, preferably as nanoparticles, dispersed in a matrix of the piezoelectric polymer.

46. The transducer of claim 45, wherein the piezoelectric ceramic is barium titanate, lead zirconium titanate, barium strontium titanate, lithium niobate, or aluminum nitride.

47. The transducer of any one of claims 37 to 76, wherein the transducer has an average diameter between about 29 nm and about 450 nm and most preferably of about 80 nm.

48. The transducer of any one of claims 38 to 47, wherein the core has an average diameter between about 5 nm and about 50 nm and most preferably of about 10 nm.

49. The transducer of any one of claims 38 to 48, wherein the electrically insulating sheath has a thickness between about 10 nm and 100 nm and most preferably of about 33 nm.

50. The transducer of any one of claims 38 to 49, wherein the electrically conducting sheath has a thickness between about 2 nm and about 100 nm, and most preferably of about 5 nm.

51. The transducer of any one of claims 38 to 50, wherein the electrically conducting sheath is made of a conducting metal,
preferably copper, silver, palladium, platinum, iridium, graphite, graphene, aluminum, titanium, or gold, or an alloy or composite thereof,
more preferably gold or an alloy or composite thereof,
most preferably gold.

52. A transistor comprising the nanowire of any one of claims 1 and 4 to 24, wherein the carbon nanotube is a semi-conducting carbon nanotube, and wherein the nanowire is surrounded by a conductive sheath.

53. The transistor of claim 52, having an average diameter between about 29 nm and about 450 nm, most preferably of about 80 nm.

54. The transistor of claim 52 or 53, wherein the core has an average diameter between about 5 nm and about 50 nm, and most preferably of about 10 nm.

55. The transistor of any one of claims 52 to 54, wherein the electrically insulating sheath has a thickness between about 10 nm and about 100 nm, and most preferably of about 30 nm.

56. The transistor of any one of claims 52 to 55, wherein the electrically conducting sheath has a thickness between about 2 nm and about 100 nm, and most preferably of about 5 nm.

57. The transistor of any one of claims 52 to 56, wherein the electrically conducting sheath is made of a conducting metal,
preferably copper, silver, palladium, platinum, iridium, graphite, graphene, aluminum, titanium, or gold, or an alloy or composite thereof,
more preferably gold or an alloy or composite thereof,
most preferably gold.

58. A method for manufacturing the piezoelectric transducer of any one of claims 37 to 51 or the transistor of any one of claims 52 to 57, the method comprising:
iii. providing a nanowire using the method of any one of claims 25 to 36, and
iv. covering the nanowire with the conductive sheath.

59. The method of claim 58, wherein step ii is carried out by physical vapor deposition, sputtering, dip coating, powder coating, electrochemical deposition, painting, plasma vapor deposition, chemical bath deposition, spray painting, screen printing, or electron beam deposition, preferably by physical vapor deposition.

60. The method of claim 58 or 59 further comprising assembling a plurality of transducers or a plurality of transistors in a bundle with their exposed ends joined with a conducting material and their conducting sheaths making electrical contact with each other.
